(19) United States
(12) Patent Application Publication
(10) Pub. No.: US 2015/0229267 A1
(43) Pub. Date: Aug. 13, 2015

(54) Apparatus for solar conversion

(71) Applicant: Donald Bennett Hilliard, El Granada, CA (US)

(72) Inventor: Donald Bennett Hilliard, El Granada, CA (US)

(21) Appl. No.: 14/544,668

(22) Filed: Feb. 2, 2015

Related U.S. Application Data
(63) Continuation-in-part of application No. PCT/US2010/002178, filed on Aug. 4, 2010.
Application No. PCT/US2010/002178 is a continuation-in-part of application No. PCT/US2011/000050, filed on Jan. 11, 2011.
Application No. PCT/US2011/000050 is a continuation-in-part of application No. PCT/US2011/000966, filed on May 26, 2011.
Application No. PCT/US2011/000966 is a continuation-in-part of application No. PCT/US2013/000063, filed on Apr. 9, 2013.

(51) Int. Cl. H02S 40/44; F24J 2/12; H01L 31/052; F24J 2/38

(52) U.S. Cl. CPC H02S 40/44; F24J 2/38; F24J 2/12; H01L 31/0525

(57) ABSTRACT

The present invention is related to the field of solar concentrators and associated energy conversion apparatus. More particularly, the invention discloses a solar tracking apparatus particularly advantageous for use with solar concentrating optics comprising compound conical concentrators, wherein modular tracking means and integration provide fast drop-in replacement, as well as low-material usage. Also disclosed are improved structures and methods for producing stackable frustum structures of the embodied optical concentrator. Additional structures specific to the inventive solar tracker are also disclosed.

### RELATED APPLICATIONS

This application is related to and claims benefit of patent applications by the same author, including (and included herein, in their entirety), U.S. provisional patent application 61/335,755 (Hilliard), filed Jan. 11, 2010, U.S. provisional patent application 61/337,338 (Hilliard), filed Feb. 1, 2010, U.S. provisional patent application 61/396,387 (Hilliard), filed May 26, 2010, U.S. provisional patent application 61/397,275 (Hilliard), filed Jun. 8, 2010, U.S. provisional patent application 61/455,576 (Hilliard), filed Oct. 23, 2010, and U.S. Provisional Patent 61/629,950 (Hilliard), filed Nov. 30, 2011, U.S. Provisional Patent 61/855,538 (Hilliard), filed May 17, 2013, U.S. Provisional Patent 61/962,009 (Hilliard), filed Oct. 28, 2013, U.S. patent application Ser. No. 12/803,213 (Hilliard), filed Jun. 21, 2010, U.S. patent application Ser. No. 13/261,526 (Hilliard), filed Nov. 26, 2012, U.S. patent application Ser. No. 13/261,486 (Hilliard), filed Oct. 21, 2012; in addition, this application is related to PCT patent applications PCT/US2010/002178 (Hilliard), filed Aug. 4, 2010, PCT/US2011/000050 (Hilliard), filed Jan. 11, 2011, PCT/US2011/000966 (Hilliard), filed May 26, 2011, and PCT/US2013/000063 (Hilliard), filed Mar. 9, 2013, as well as any other related patent applications of the aforementioned applications, all of which above-mentioned applications are each and all included herein by reference, in their entirety. All claims of the presently filed application claim benefit of pre-AIA applications, and therefore are filed under pre-AIA provisions.

### FIELD OF THE INVENTION

The present invention is related to the field of concentrated solar apparatus and associated solar tracking apparatus, used in the generation of electrical, thermal, and chemical energy. The present invention also relates to solar receiver modules utilized in conjunction with concentrated solar energy.

### BACKGROUND OF THE INVENTION

A primary obstacle in the commercialization of solar energy conversion devices, whether with regards to solar-thermal, solar photovoltaic's, concentrated solar systems, etc, comprises the need to simultaneously minimize manufacturing costs while maintaining physical tolerances and durability necessary to retain a desired efficiency and device lifetime. In segments of the solar energy industry utilizing a solar concentrator or condenser, the challenge to reduce manufacturing costs is most significant in the solar collector design, as the component generally requiring the greatest materials expense. A crowded array of art has been introduced to address this challenge, including, broadly speaking, such relatively large solar concentrators as linear trough systems and linear Fresnel systems, dish systems including parabolic and compound reflectors. Also, various, typically in conjunction with photovoltaics, concentrators have been utilized in solar panels that incorporate a periodic array of concentrators that couple to a receiver. Within these broad groups of concentrating means are utilized a vast assortment of optical designs that, while utilizing well-known refractive, diffractive, and reflective properties of well-known and understood optical components, are primarily advanced on the basis of a particularly advantageous manufacturing approach involving a proprietary geometric optics design, which in turn is expected to deliver a desirable cost per kilowatt delivered.

A problem with these various solar concentrators of the prior art is their reliance on proprietary system components that require widespread adoption of a narrowly applicable optical system as a precondition to a projected cost performance. In addition, these system components are typically plagued by materials development issues that are unique to the particular system in question and its operational characteristics. These system-specific materials challenges result in circumstances wherein expending resources on materials development will be compensated only if the specific solar application addressed is successfully commercialized, thus increasing investment risks.

There is therefore a need in the solar industry for a solar concentrator that provides, relatively to previous designs, much higher strength-to-weight ratio and rigidity-to-weight ratio, this with a commensurate savings in manufacturing cost, and while providing an inherently high-precision tooling and manufacturing platform; in addition, it is more preferable that this solution be in a concentrator format that enables utilization broadly across numerous segments of the concentrating solar industry, so that such a concentrator is readily adaptable to both a wide range of concentration ratios and solar energy-conversion processes.

Multi-frustum concentrators have been proposed in the past for providing solar concentration; however, while these solutions have been proposed for several decades, commercialization of such optical geometry has never been actively pursued. This may be readily understood as a consequence of such previous designs lacking a demonstrable concentration efficiency, as well as failing to present a compelling manufacturing advantage over the more commonplace parabolic, aspheric dishes and fresnel lens systems that have come to dominate high concentration solar.

As example, in the 1970's, Dane (U.S. Pat. No. 4,743,095) taught multi-frustum concentrators that comprising reflective sheet metal supported on metal frame construction, similar to manner that parabolic concentrators are constructed of segmented reflectors mounted onto metal frames. However, the Dane reflector was inherently low-concentrating, requiring relatively long absorber lengths to absorb substantially all reflections of direct normal irradiation from the segmented reflector, as was evidenced both in its illustration and description. Furthermore, the reflector design was inherently materials-intensive, since the reflective material required support by a rigid metal structure that required similar mass as to that incorporated in parabolic dish support structures. Hence, the advantages of such early multi-frustum reflectors were limited. Subsequent examples of this concentrator type have not substantially altered this situation.

The prior art does not reveal a multi-frustum concentrator having the high concentration ratios afforded to practical parabolic dish concentrators of the solar art, nor does it provide an approach suggesting such concentration ratios are possible. In addition, such reflectors of the prior art require manufacturing costs that, as a matter of historical record, are not found sufficiently attractive to compete with existing solar concentration means.

### SUMMARY OF THE INVENTION

In accordance with the preferred embodiments, a solar tracking apparatus is embodied for 2-axis tracking of a compound conical concentrator (CCC) as embodied in related applications, which are included herein in their entirety by reference. The inventive tracker is particularly suited for light-weight and/or deployable applications, wherein assembly and disassembly of a relatively large, 2-axis, tracker, can be quickly executed. Similarly, separate functions of the tracker are separated into modular components that are readily swapped out, so that field repair requires minimal time or expertise.

In the preferred embodiments, a solar tracking apparatus is disclosed, which provides means for tracking concentrated solar systems of the centrosymmetric geometry, particularly of the type utilizing central feed-through of HTF an electrical conductors at the central base of the centrosymmetric optic.

Another advantage of the present invention is the incorporation of a drop-in tracker module which is mounted by insertion into a socket/receptacle having required electrical and/or heat transfer fluid (HTF) connections positioned therein.

Another advantage of the present invention is a 2-axis solar tracker that provides for removal and mounting of its optical concentrator by means of a fastener array located at the center of the concentrator.

Another advantage of the present invention is to provide a 2-axis solar tracker that provides for removal and mounting of its optical concentrator by means of a fastener array located at the center of the concentrator, wherein electrical and fluid connections are provided into the optical concentrator by passing through a hollow member that is integral to the fastening means.

Another advantage of the present invention to provide a 2-axis solar tracker that provides for removal and mounting of its optical concentrator by means of a fastener array located at the center of the concentrator, wherein electrical and fluid connections are provided into the optical concentrator by passing through a hollow member that is integral to the fastening means.

Another advantage of the present invention is provided in a 2-axis, altitude-azimuth mount, solar tracker that provides altitude adjustment by means of a linear bearing located within the tracker's mount post.

Another advantage of the present invention is provided in a 2-axis, preferably altitude-azimuth mount, solar tracker that provides altitude adjustment by means of a modular tracking assembly that is demountable by means of insertion into a pipe-mounted socket.

Another advantage of the present invention is a 2-axis solar tracker incorporates a modular tracking assembly including dual motor drives and integrated coaxial rotating unions, so that both mechanical movement and fluid connections are provided at the same connection flange.

It is accordingly preferred, in the telescoping embodiments, that the individual conical frustums of the present invention are constructed so that upper and lower edge-surfaces of the frustum structures are terminated as a cylindrical surfaces having central axis coincident with the optical axis, so the reflective, inwardly facing frustum surface and outer-facing frustum surface are interconnected and terminated at both upper edge-surface and lower edge-surface by these adjoining cylindrical surfaces.

In a further preferred embodiment, improved methods and structures are disclosed for fabricating CCC's of use in the embodied solar concentrating applications. In particular, with reference to the previously disclosed individual frustum and resultant multi-frustum CCC's of the referenced patent applications, a substantially hollow-core frustum structure is disclosed incorporating identical attributes of the previously disclosed hollow-core frustums, except that an alternate spacer means is provided for providing reinforcing structural members between the two separated layers of the inventive frustum.

Whereas the previous frustum structures incorporated a separate, corrugated, preferably metal, core structure (e.g., honeycomb core structure), the present invention provides reinforcing structures by means of a periodic dimpling of the outer layer, wherein a concentric hole structure in each dimple feature provides means for injecting a resin meniscus, or concentric bead, at the closest proximity between the dimple feature of the outer layer and the adjacently disposed inner layer of the frustum structure, so that the completed frustum, with evenly spaced inner layer and outer layer, is formed so as to have a hig density of such small dimple features, each adhered to the inner layer by means of a resin meniscus formed by injection of the resin through the dimple hole to contact the adjacent inner layer of the frustum, wherein the resin forms a deposited shape not larger than three times the diameter of the concentric hole formed in the dimple feature.

Another objective of the presently embodied invention is to provide improvements in previously disclosed apparatus and methods in constructing discrete, stackable frustum structures for creating multi-frustum concentrators, or compound conical concentrators. Preferably a multitude of segments are constructed, wherein each segments is formed having an array of many cone-shaped indentations in the segment, wherein the cone-shaped indentations are formed so as to each converge toward a central peak centered on a central axis, wherein the resulting cone-shape indentation is preferably formed having a truncated shape, such that the central axis intersects a concentric opening in the small end of the cone-shaped indentation.

Another advantage of the present invention is to provide a compound conical concentrator in which a base mount structure is disposed to support the concentrator and its associated tracking apparatus disposed for tracking the concentrator, the mount structure comprising a treated fabric, or textile, covering, the fabric covering preferably formed to have a roughly conical aspect, wherein the conical aspect of the mount structure is disposed such that the tracking apparatus is located at the relatively elevated and smaller end of the conical aspect. In accordance with the embodied tension-tent attributes of the embodied tracker base, the fabric covering is tensioned to form a roughly centrosymmetric profile, wherein stress-strain attributes of the material result in a curved, preferably concave aspect of the resultant covering.

A further advantage of the invention is provided in the embodiment of a novel roof covering that integrates a multitude of the disclosed tracker apparatus into a building structure.

Yet another advantage of the invention is provided in the embodiment of a novel solar tracker providing means to enable a wind-canceling geometry to be engaged by combination of two opposing, roughly cone-shaped structures, namely a concentrator of the preferred embodiments and opposing tension-tent covering of the embodied concentrator base, wherein locking means are disposed for locking relative position of the two roughly cone-shaped structures, whereby wind passing between the two cone-shaped structures will be incident on inclined surfaces of each so as to create forces in opposite directions, thereby canceling net force exerted on the overall solar tracking assembly.

Another advantage of the invention is to provide a modular, demountable, receiver-tube assembly having demountable interconnects for HTF, power, and sensor electronics, disposed at one end of the assembly.

Yet another advantage of the invention is to provide a combined-heat-and-power, demountable solar receiver tube that can be readily adapted to a wide range of concentration ratios, concentrator sizes, and power loads.

Yet another advantage of the invention is in providing an assembly of linear multi junction photovoltaic (MJPV) arrays into a single, larger circuit comprising a modular, linear, polygonal (MJPV) array.

Another advantage of the invention is to provide a multi-frustum concentrator maintained under a compressive force by means of a tensioned fabric cover disposed along its external surface.

Yet another advantage of the invention is in providing a demountable MJPV linear-array module having demountable electrical and heat-transfer-fluid (HTF) attachments.

Other objects, advantages and novel features of the invention will become apparent from the following description thereof.

### BRIEF DESCRIPTION OF THE DRAWINGS

FIG. 1 is a sectional side-view of the invention in its preferred embodiments, a solar tracking apparatus (300), taken through a plane containing axis (62) and axis (73), wherein, such central axes are axes of circular symmetry for drawing elements depicted as symmetric about these axes and embodied as circular elements. The invention is depicted without preferred cover (421) for purposes of disclosure.

FIG. 2 is a perspective view of the solar tracking apparatus (300) in its preferred embodiments

FIG. 3(a-b) comprises (a) a top view of a base-mount assembly (400) of the invention in its preferred embodiments, and, (b), a schematic side view of the invention in its preferred embodiments base-mount assembly (400) shown with demountable tracking assembly (227) in accordance with the preferred embodiments.

FIG. 4(a-b) comprises (a) a perspective view of a base-mount assembly, and, (b) a perspective view of the base-mount assembly with a tension-tent covering in accordance with the preferred embodiments.

FIG. 5(a-b) comprises (a) a sectional side-view of a base-mount tube assembly and attached hub structure in accordance with the preferred embodiments, and, (b) a side-sectional view of a base-mount support rim assembly (405) of a base-mount assembly in accordance with the preferred embodiments, with sectional views taken through a plane containing axis (62)

FIG. 6(a-b) comprises (a) a side-view of, and, (b) a top view of a demountable tracking assembly in accordance with the preferred embodiments.

FIG. 7 is a schematic sectional side-view of a demountable tracking assembly in accordance with the preferred embodiments, sectional view taken through a plane containing axis (62) and axis (73)

FIG. 8(a-d) comprises (a) a top end view, (b) a bottom end view, (c) a perspective view, and, (d) a side-view of a tracker rotating-carriage assembly in accordance with the preferred embodiments.

FIG. 9(a-b) comprises (a) a perspective view, and, (b) a cut-away view of a tracker static-base assembly and rotating unions in accordance with the preferred embodiments.

FIG. 10(a-c) comprises (a) a sectional view of altitude/tilt rotating-union assembly (382) in accordance with the preferred embodiments, sectional view taken through a plane containing axis (62) and axis (42), (b) a perspective view of the expanded assembly of the altitude/tilt rotating-union assembly in accordance with the preferred embodiments, and, (c) a side-sectional view of a tracker static-base assembly in accordance with the preferred embodiments.

FIG. 11(a-b) is a side-sectional view of a demountable tracking assembly, with sectional view taken through a plane containing axis (62) and axis (73), and (b) is a top sectional view of a demountable tracking assembly, sectional view, taken through section plane (228)

FIG. 12(a-b) comprises (a) a sectional side-view of a receiver tilt assembly (RTA), taken through a plane containing axis (73), and, (b) a perspective back view of the RTA, in accordance with the preferred embodiments.

FIG. 13(a-c) comprises (a) a side view of a frustum structure in accordance with the preferred embodiments, (b) a perspective view of the frustum structure (80), and (c) is a closed-caption view of a dimpled structure comprising outside-facing surface of an embodied frustum of the preferred embodiments, comprising closed caption box (312) in FIG. 13a.

FIG. 14(a-b) comprises (a) is a side-sectional view of a dimple structured frustum wall in accordance with the preferred embodiments, sectional view taken through a plane containing centerline (315) and axis (316), and (b) is a is magnified closed-caption top view of the side-sectional view, corresponding to closed caption box (321) in FIG. 14a.

FIG. 15(a-b) comprises (a-b) a sectional side-view of a dimple press in accordance with the preferred embodiments, taken through a plane containing axis (330).

FIG. 16(a-c) comprises (a) a side-view, (b) a perspective view, and (c) is a front view of a solar-tracking apparatus in accordance with the preferred embodiments.

FIG. 17(a-c) comprises perspective views of a roof-mounted solar-tracking assembly in accordance with the preferred embodiments.

FIG. 18(a-b) is a modular receiver tube comprising (a) a sectional side-view of a sealed-glass tube assembly (702) of the preferred embodiments, with section taken through plane P₁, and (b) a sectional side-view of a modular receiver tube (707) of the preferred embodiments, with section taken through plane P₁.

FIG. 19(a-b) is, (a) is a front-sectional view of an a core-insert assembly of the first preferred embodiments, section taken through plane P₂ in FIG. 18b, and (b) is a perspective view of an assembled core-insert assembly (700), base mount assembly (770), and conductor assembly (780) of the preferred embodiments.

FIG. 20(a-b) is, (a) a side-sectional view of a receiver tube's core-insert assembly of the preferred embodiments, with section taken through plane P₁, and, (b) a side-view of the core-insert assembly as mounted on a conductor assembly (780) of the preferred embodiments.

FIG. 21(a-d) is a receiver tube's conductor assembly (780) of the preferred embodiments, comprising (a) a front view of the conductor assembly, (b) a perspective view of the conductor assembly, (c) a side-view of the conductor assembly, and, (d) a perspective view of a subassembly of the conductor assembly.

FIG. 22(a-d) is a receiver tube's core-manifold structure in a preferred embodiment, comprising, (a) a combined front and side views, (b) a perspective view, (c) front-sectional view, with section taken through plane P₂, and, (d) a side-sectional view of the core-manifold structure, with section taken through plane P₁.

FIG. 23(a-c) is a linear-insert substrate of the preferred embodiments, comprising (a) a perspective view of in a first alternative preferred embodiment, and (b) front sectional views, section taken through plane P₂ of FIG. 23c, in view (A.) and section taken through plane P₄ of FIG. 23c, in view (B.), and, (c) successive views A-D, comprising side-view, top-view, bottom-view, and side-sectional view, with side-sectional view taken through plane P₁.

FIG. 24(a-c) is a “spine” assembly (730) of conductors of the preferred embodiments, comprises (a) combined views A-D of a “spine” contactor element, in a first alternative preferred embodiment, and (b) a perspective view of the “spine” contactor element, and, (c) a “spine” assembly.

FIG. 25(a-c) is a diode tape assembly of the preferred embodiments, comprising, (a) a side sectional view of the diode tape, (b) a broken-out perspective view, and, (c) a broken out side-view of the diode tape incorporated into a diode-spine assembly (750).

FIG. 26(a-b) is a side-contactor tape (or “side-tape”) assembly of the preferred embodiments, comprising, (a) a sectional view of the side-contactor tape, section taken through plane P₂, and, (c) a broken-out perspective view of a segment of the side-tape assembly.

FIG. 27(a-c) is an insert top-plane assembly (760) of the preferred embodiments, comprising (a) successive views A-C of a mounted-die assembly (761), comprising top-view, side-sectional view, and bottom-view, respectively, (b) a side-sectional view of mounted-die assembly attached to linear-array substrate, taken through plane P₂, and, (c) a schematic perspective view of a top-plane assembly.

FIG. 28(a-c) is a linear insert assembly (720) (“ITPA”)) of the preferred embodiments, comprising (a) a side-view showing an assembly sequence for assembly of the linear insert assembly, (b) a side-view of the assembled linear insert assembly, and, (b) sectional-view of the linear insert assembly, with section taken through plane P₂.

FIG. 29(a-b) comprise broken-out perspective views of the linear insert assembly in its preferred embodiments, comprising, (a) perspective view of the linear insert assembly with insert top-plane assembly (“ITPA”) removed so as to view underlying conductor assembly, and (b) perspective view of a completed linear insert assembly, with ITPA attached.

FIG. 30(a-b) is a modular receiver tube in accordance with the preferred embodiments, comprising, (a) a rear perspective view of the receiver tube, and, (b) a front perspective view of the receiver tube in conjunction with an associated mounting receptacle.

FIG. 31 is side-sectional view, with section taken through plane P₁, of a modular receiver tube inserted into a mounting receptacle/nipple in accordance with the preferred embodiments.

FIG. 32(a-b) is (a) a polygonal, octagonal, end-mirror of the preferred embodiments, and, (b) is side-sectional view of a straight-walled receiver tube in an alternative embodiment, with section taken through plane P₁,

FIG. 33(a-b) is a frustum core-structure for use in a multi-frustum concentrator, comprising plan-views of two concentric arrays of ring-shaped elements incorporated into the frustum structure. FIG. 33a, comprises pan view, (A.), and associated side-sectional view (B.) with section taken through sectional plane (474) intersecting central axis (73) of the concentric arrangement of cylindrical rings. FIG. 33b, comprises pan view, (A.), and associated side-sectional view (B.), with section taken through sectional plane (476) intersecting central axis (73) of the concentric arrangement of lateral rings.

FIG. 34(a-b) is a frustum structure for use in a multi-frustum concentrator, comprising (a) side sectional view, section plane taken through central axis (73), and (b) a side sectional view in an alternate preferred embodiment.

### DETAILED DESCRIPTION OF THE PREFERRED EMBODIMENTS

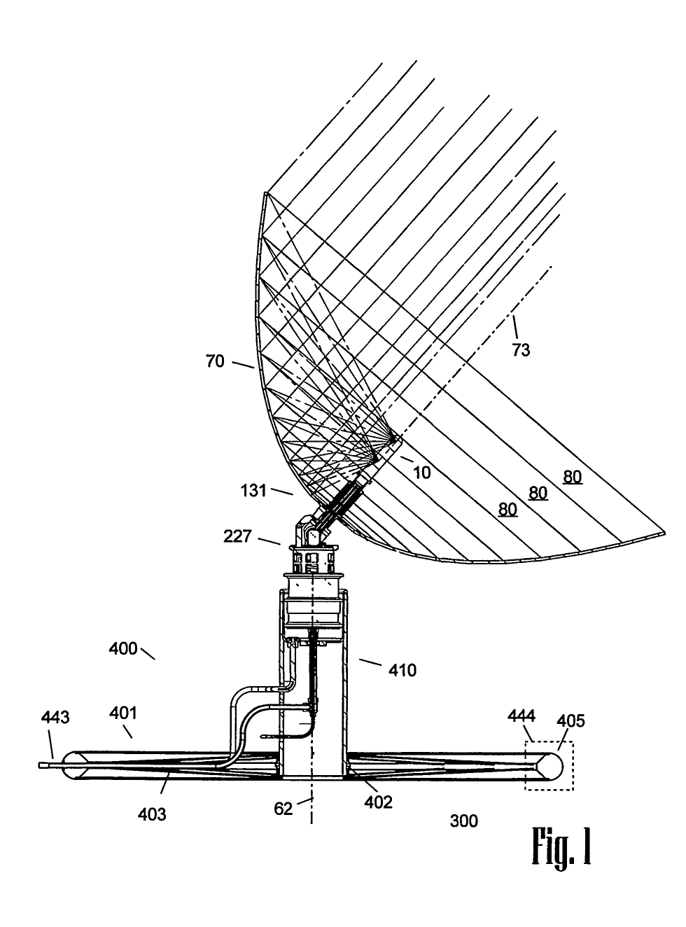

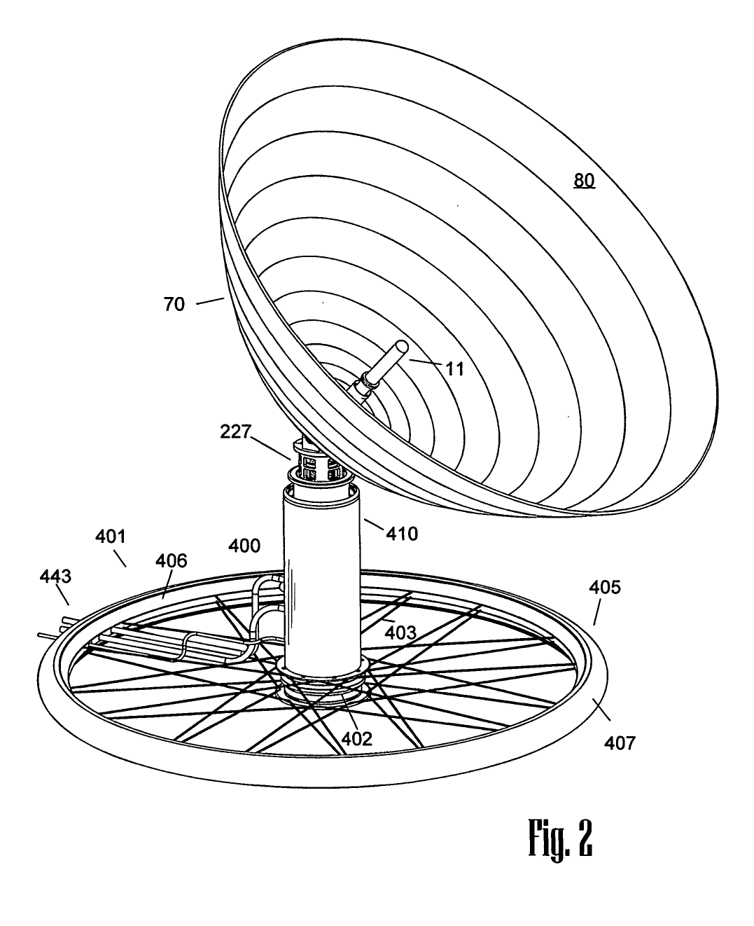

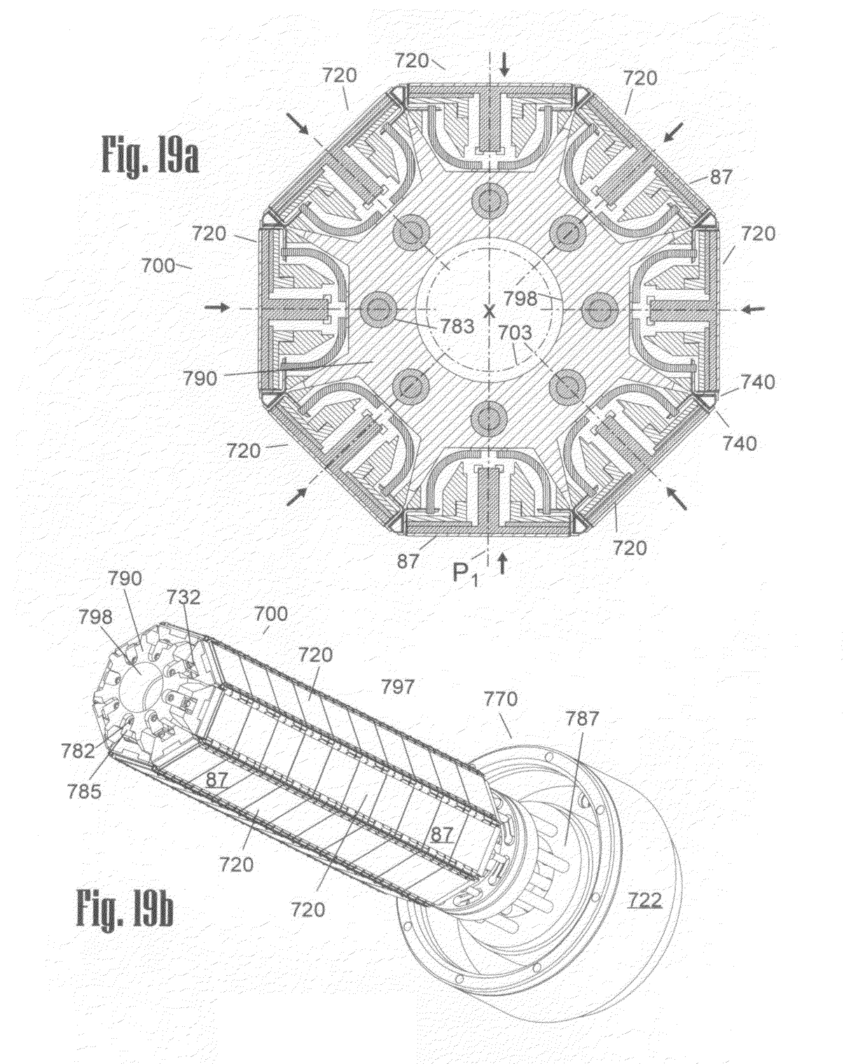

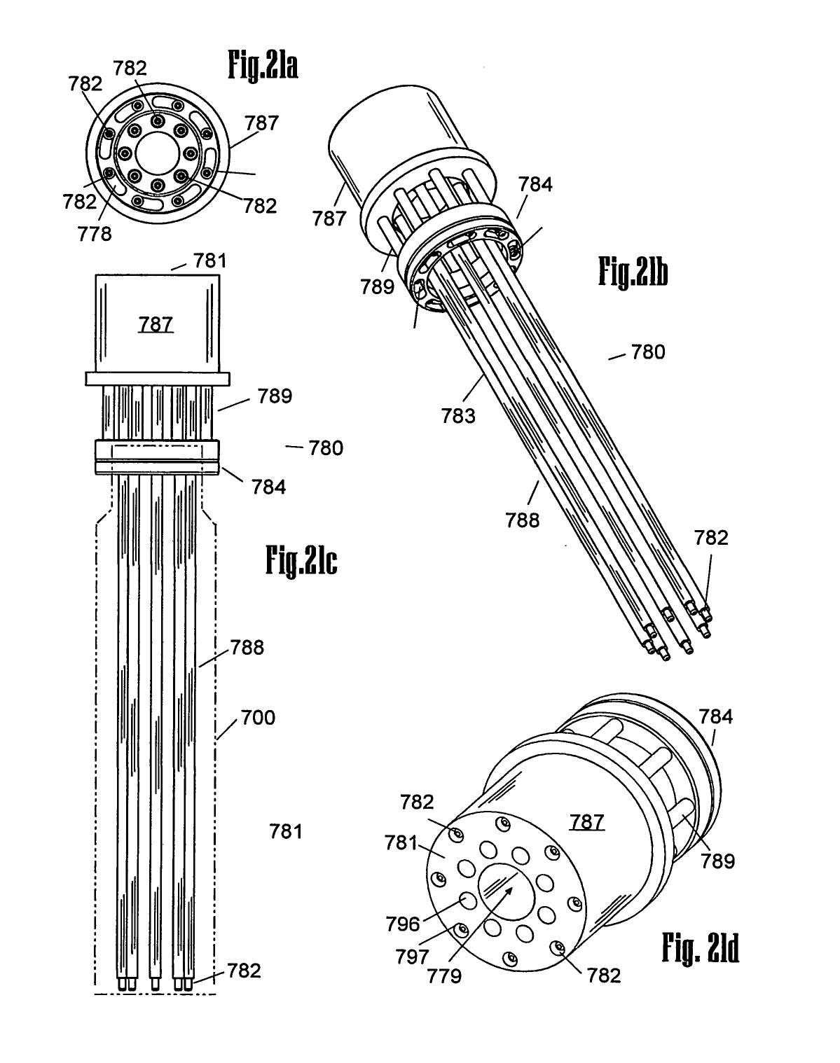

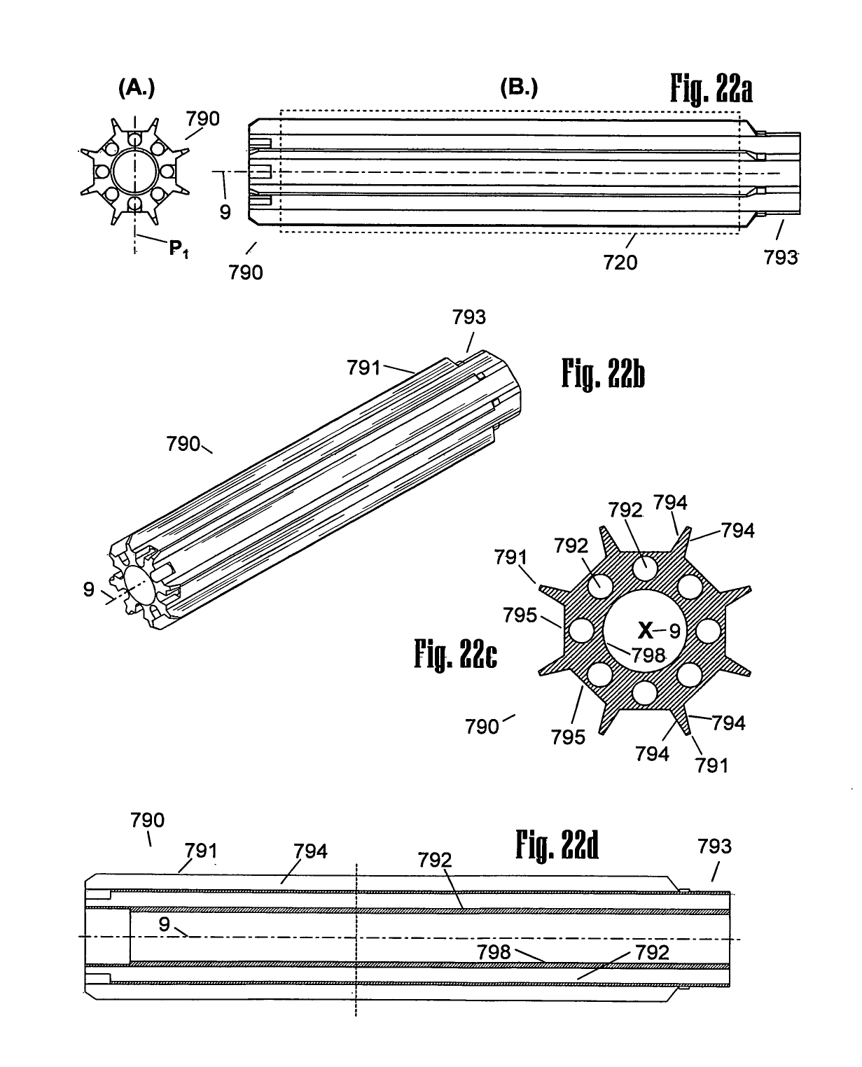

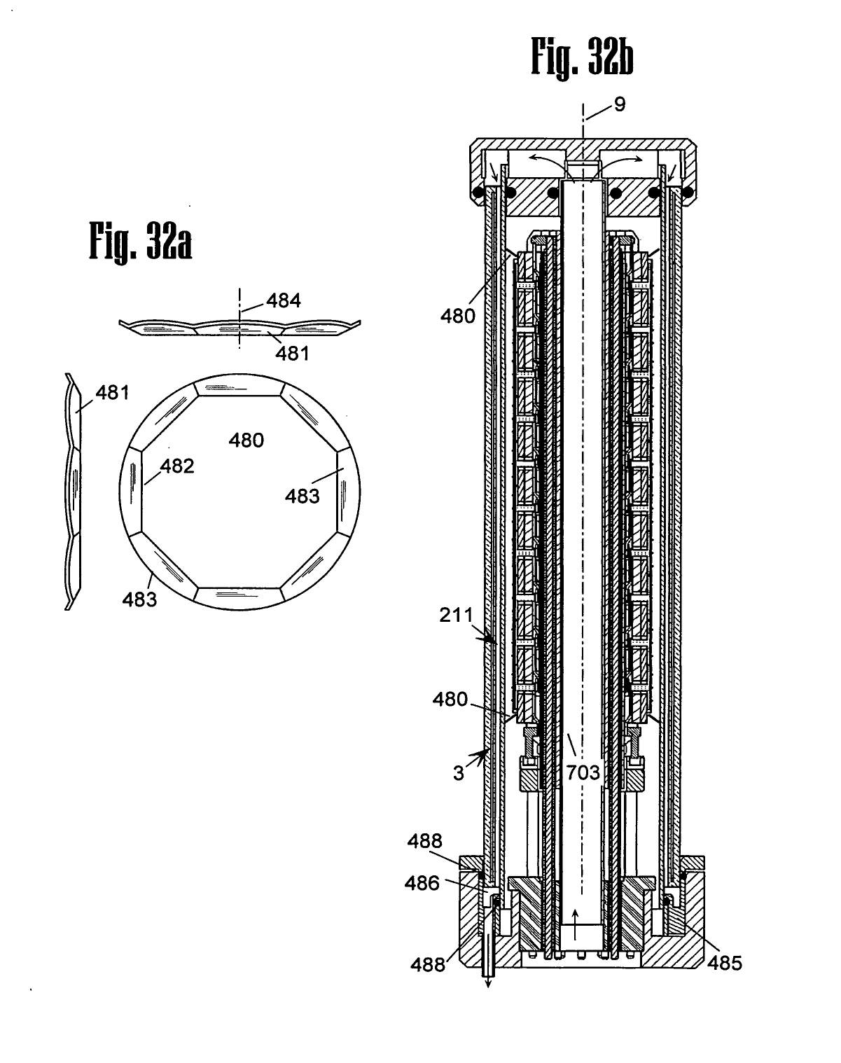

The following description and FIGS. 1-34 of the drawings depict various embodiments of the present invention. The embodiments set forth herein are provided to convey the scope of the invention to those skilled in the art. While the invention will be described in conjunction with the preferred embodiments, various alternative embodiments to the structures and methods illustrated herein may be employed without departing from the principles of the invention described herein.

In the first preferred embodiment, a compound conical concentrator (70), or CCC, with central optical axis (73), as previously disclosed in aforementioned patent applications, is utilized in a particular arrangement and apparatus so as to enable a multiple advantages, particularly in the intermediate solar-thermal range. In its preferred embodiment, the CCC is supported and tracked by means of a demountable tracking assembly (227), or DTA, which preferably comprises a two-axis tracking mechanism, providing both altitude (or tilt) adjustments and azimuth (or pivot) adjustments, having integrated coaxial fluid passageways, and wherein such integrated solar-thermal tracking apparatus is fitted with a demountable interconnect assembly that enables tool-less and quick exchange of such integrated DTA modules as drop-in modules. Accordingly, such demountable modules are fitted with demountable electrical and liquid connections on the surface of the module interfacing to an underlying support structure. In the preferred embodiments, the integrated tracking module is mounted onto a (BMA) base-mount assembly (400) that provides mechanical support for the DTA and CCC, as well as an internal assembly of electrical and fluid (may be gas or vapor) passageways that convey electrical current and heated fluids to an external interconnection assembly and load. In its first preferred embodiment, the BMA comprises as foundational structure providing a wide base relative to its apex, so that support of the embodied tracking array may be provided by an architectural roof or similar surface, without need of reinforcements such as large mechanical roof penetrations, or concrete footings.

Accordingly, the base-mount tube (410) and associated base-mount tube assembly (426) is positioned and supported by a wide-based (SWA) spoked wheel assembly (401) comprising base-mount hub (402), spokes (403), and base-mount support rim assembly (405.

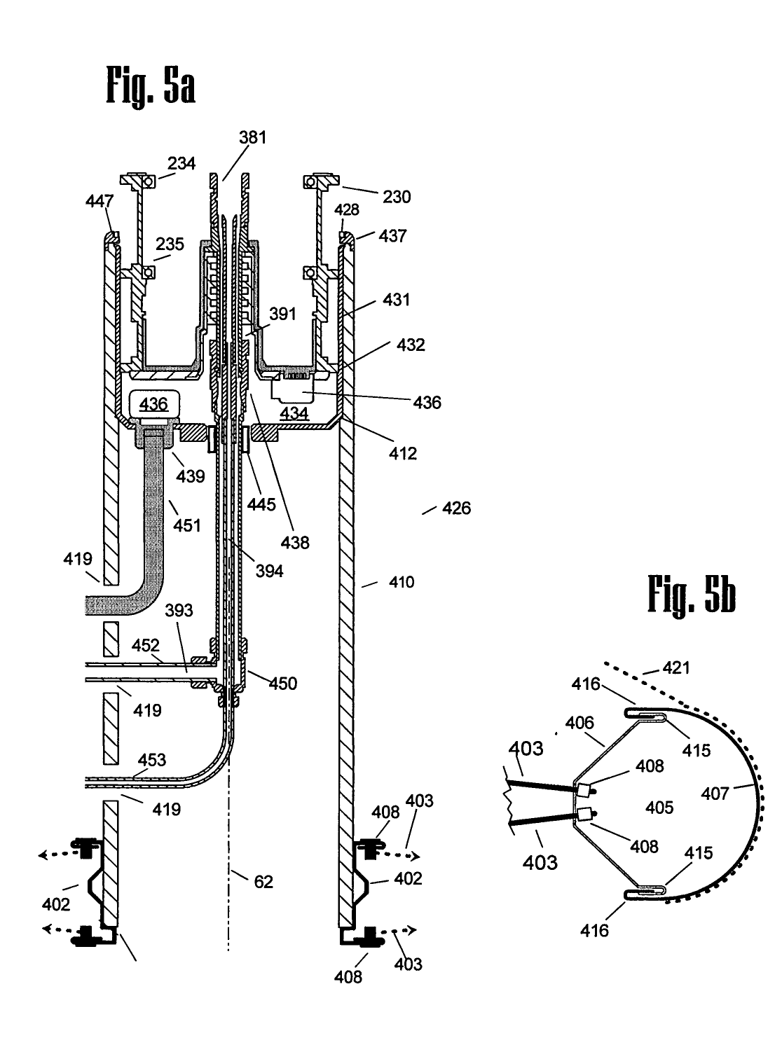

It is additionally preferred that the relatively wide BMA base comprise a spoked structure, namely a (SWA) spoked wheel assembly (401), utilizing mechanical attributes similar to bicycle wheels, in that strength-to-weight ratio is enhanced by means of radial support elements preferably maintained under tensile stress, similar to spokes of a bicycle wheel. The spokes (403) of the SWA (401) are connected centrally to a base-mount hub (402) that is fitted with appropriate spoke fasteners. The base-mount support rim assembly (405) comprises base-mount support inner rim (406) and base-mount outer shell (407), which are embodied in greater detail in FIG. 5.

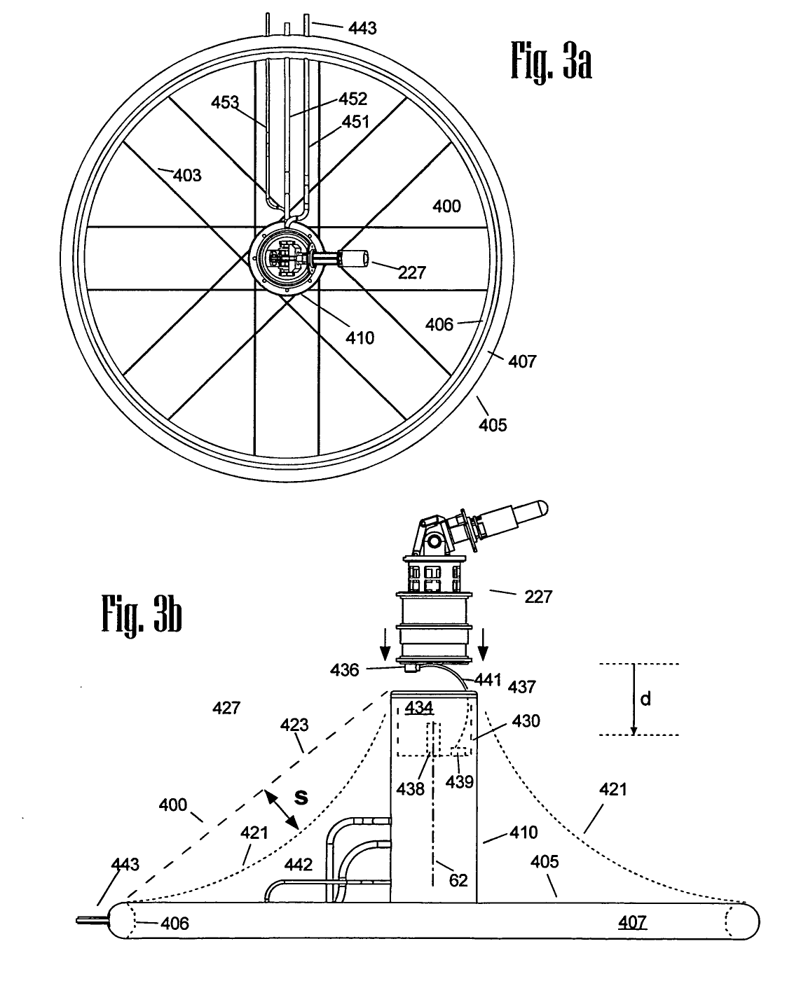

In a further preferred embodiment, in FIG. 3-5, the DTA is demount-ably inserted as a drop-in module into the BMT (410), wherein means for accepting the DTA is accordingly located. Receptacle means, namely, a base-mount receptacle (BMR), is accordingly fitted in the associated tube interior and providing connection to servicing base-mount utility conduit (442) comprising base-mount electrical conduit (451), base-mount supply pipe (452), and base-mount return pipe (453), wherein each of these three conduit structures are preferably disposed to direct flow of electrical current and heat transfer fluid to a peripheral interface region, namely BMA interface region (443), in FIG. 5. The resulting, underlying, support-and-tracking structure (427) of the embodied CCC (70) comprises the combination of base-mounting assembly (BMA) and inserted DTA (227), whereby, after removal of the light-weight CCC (70), the DTA is readily mounted or demounted from the BMA.

The DTA is insertable as drop-in module into the BMR within base-mount receptacle (BMR) interior volume (434) formed by BMR dish structure (431) within the BMT; the DTA is accordingly inserted or removed from the BMA by vertical displacement, preferably executable by a single human. Various individual locking and/or latch mechanisms may be additionally implemented to additionally secure the DTA. It is particularly preferred that the insertion distance, d, required to move the DTA between a mounted to a fully removed position be roughly equivalent to d, wherein d is a spatial dimension in the range, 3 inches≦d≦12 inches.

In particular, the DTA is preferably inserted into the supporting BMA by means of an accordingly circular receptacle, namely, the base-mount receptacle (BMR) assembly (430), which incorporates BMR dish structure (431), which is disposed at the upper region of and inside the base-mount tube (410).

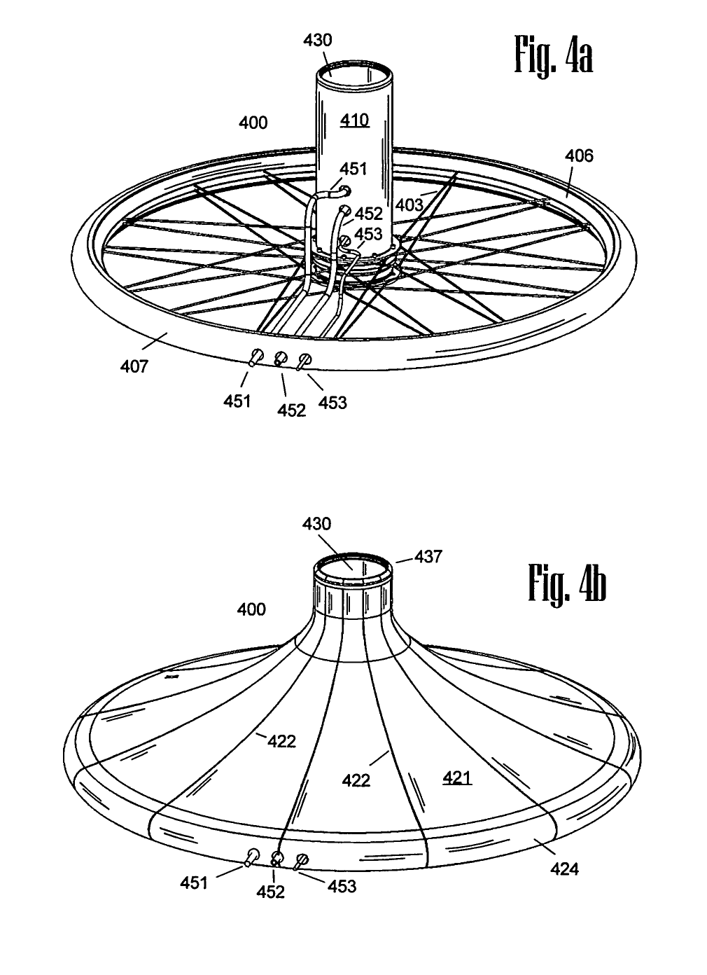

Utility conduit for providing communication of electrical current and HTF are interfaced to an external hook-up located preferably at the periphery of the BMA at a base-mount utility interconnect region (443), although an alternative embodiment may have the interconnect region located directly below the base-mount tube (410), such as in certain roof installations.

Whereas the previous structural embodiments may be deployed with a variety of panels or facades for providing protection, structural reinforcement, or cosmetic attributes, it is preferred, in FIG. 3-4, in particular, that a protective covering comprising a flexible, water-proof, sheet material, preferably an appropriately treated fabric or textile in the form of a tension-tent covering (421), which provides protection, structural reinforcement, wind-force cancellation, and cosmetic attributes.

The tension-tent cover (421) accordingly provides an external shape and appearance similar to tension-tent structures utilized in various covered structures, commonly recognized in the art of tents and fabric-covered pavilions. In accordance with characteristics generally attributed to tension tents, the tent profile, in its tensioned state, is not precisely conical, but deviates from linear conical profile (423) by a tension-tent sag dimension, s, which results from the tensioning of the tent material (421). This distance from a linear profile, the “sag”, or, s, in FIG. 36, is preferably provided such that the ratio of s/L, where L is the length of the tensioned segment (423), is such that this ratio is in the range, 0.02≦s/L≦0.5, though values outside of this range may be implemented.

In accordance with the tension-tent's stretched, or tensioned, attributes, it is also preferred that tension tent exert a tensioned force to the BMT at the upper region of the BMT where it is attached, the tension tent preferably being attached to the BMT at the specified ring/step assembly (447) (437) (428) located at the top of the BMT. In accordance with the prior art of tension tents, it is also preferred that the tension tent force exerted by applied evenly around the supporting BMT, so that the force exerted by the tension tent is operative in positioning and reinforcing the central and orthogonal relationship of the BMT with respect to the underlying base, preferably disposed as the embodied spoke-wheel assembly (SWA).

Such architectural fabrics utilized in tent-like coverings of the present invention include polymer-reinforced and/or impregnated fabrics (including non-woven fabrics), wherein it is preferably a coated polyester fabric, and more preferably a PVC-coated polyester (e.g, polyvinylchloride-coated), such as provided by such recognized companies as Shelter-Rite, HighTex, Mehler, Plastatec, and others. In an alternative preferred embodiment, the fabric covering is a coated/impregnated fiberglass fabric, more particularly a PTFE (i.e., polytetrafluoroethylene, or Teflon) coated fiberglass fabric, commercially available through such manufacturers as Precision Coatings, Inc., Taconic, and others. Alternatively the fabric may be a PVC, nylon, Dacron, cotton, wool, or any other appropriate fabric, that is coated with any appropriate polymer, including silicone or other polymer. Alternatively, the fabric may be substituted by a metallic sheet.

The BMR accordingly has interior surfaces forming interior volume (434) into which the DTA (demountable tracking assembly) is inserted. The complementing coaxial fluid connectors of the DTA and BMR are thereby centrally aligned so as to engage one another, so that a continuous fluid circuit is provided between the two components.

base-mount receptacle (BMR) assembly (430) also comprises, in FIG. 5a, a coaxial fluid connector (438) and electrical interconnect (439), which are mounted at the bottom of base-mount receptacle (BMR) assembly (430) and disposed so as to be demount-ably connected to the DTA (227). Accordingly, coaxial fluid connector (438) is configured so as to have a mating relationship to a mating connector (391) in the DTA, and the electrical connector (436) is connected to the DTA by means of a tracker interconnect cable (441). that enables connection to the DTA by means of electrical connectors (436) fastened at either end of the interconnect cable.

The feed-through's mounted within the BMTA (426) preferably include a central coaxial fluid connector (438), which provides fluid communication to the DTA for transporting a heat transfer fluid. Accordingly it is preferred that the BMR coaxial fluid connector is fastened as a feed-through structure through central opening located centrally in the base of the BMR dish structure (431), preferably insulated from the remaining BMR by means of base-mount receptacle (BMR) fluid insulating sleeve (445). The base-mount receptacle BMR electrical interconnect (439), which provides electrical connection to the DTA (227), preferably by means of BMR tracker interconnect cable (441) and connectors (436) is also mounted in base of the BMR dish structure (431).

In accordance with the preferred embodiments, the base-mount hub (402), as part of the SWA, supports the upright support tube structure comprising Base-mount Tube (410) and other elements comprising base-mount tube assembly (426), or BMTA, in FIG. 5a. In particular, and in accordance with the figures, it is preferred that base-mount hub (402) is constructed as a circular ring structure having circular symmetry about the central tilt/azimuth axis (62) within the BMA. In the preferred embodiments, the hub structure is a circular element rotationally symmetric about central axis (62), and accordingly, is similarly fabricated and structured as automobile rims, by methods utilized in automobile and bicycle manufacturing industry, using the same well-known methods, such as metal spinning, turning/cutting, and continuous sheet metal forming and stamping.

The BMTA (426) thereby comprise receptacle means for enabling demounting and exchange of the DTA (227). Accordingly, a base-mount receptacle (BMR) assembly (433) is disposed and located within the top region of the Base-mount Tube (410), and comprises base-mount receptacle (BMR) dish structure (431) and its associated fasteners and feed-through's. It is preferred that the BMR dish structure (431) is contacted and registered against a base-mount receptacle (BMR) tracker step-surface (432), which is preferably formed as a step in the within the Base-mount Tube (410), in FIG. 5(a).

Tension tent reinforcement straps (422) are preferably incorporated as reinforcement and strengthening of the tension tent tensile strength, wherein such reinforcement means are preferably imbedded in the tension tent material and not externally visible, and serve to further reinforce the overall structural integrity of the embodied base mount assembly.

A tension-tent top fastening means, preferably comprising ring structure (428), is utilized to secure the top of the tension tent (421) to the top of the upright tube (410) and thereby allow stretching of the tension tent in accordance with the tension-tent characteristics, in FIG. 4-5.

Accordingly, the tension tent (421) is stretched between such top tent-fastening means (428) comprising the embodied ring structure, and an opposite tent-fastening means located at a peripheral region of the base-mount structure, preferably at the base-mount rim assembly (405) incorporated into the fastening surfaces (415) (416) thereof. It is therefore preferred that base-mount tube assembly preferably incorporates a ring element (437) that enables securing of the tent cover by way of stepped profile (447) for receiving tent fastening/tensioning ring (428).

As indicated previously, it is preferred that the base-mount support rim assembly is constructed as a circular wheel structure having circular symmetry about central tilt/azimuth axis (62) within the BMA, such that the SWA preferably comprises a concentric arrangement of elements and arrangement similar to light-weight bicycle wheels of the bicycle art. In particular, the base-mount support rim assembly comprises, in FIG. 5b, support rim mounting surface (415) that engage outer shell mounting surface (416), so as to form a reinforced rim assembly. Spoke fasteners (408) are utilized for fastening and/or tensioning steel spokes (403) to the inner rim (406), as is commonly performed in bicycle wheel fabrication.

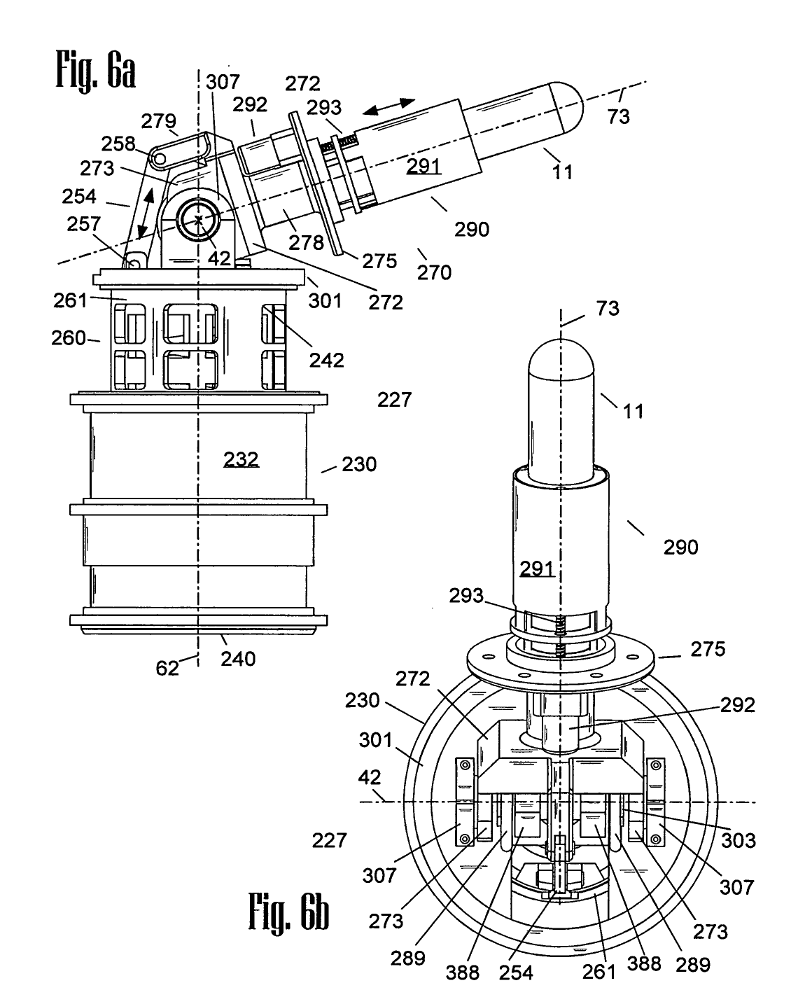

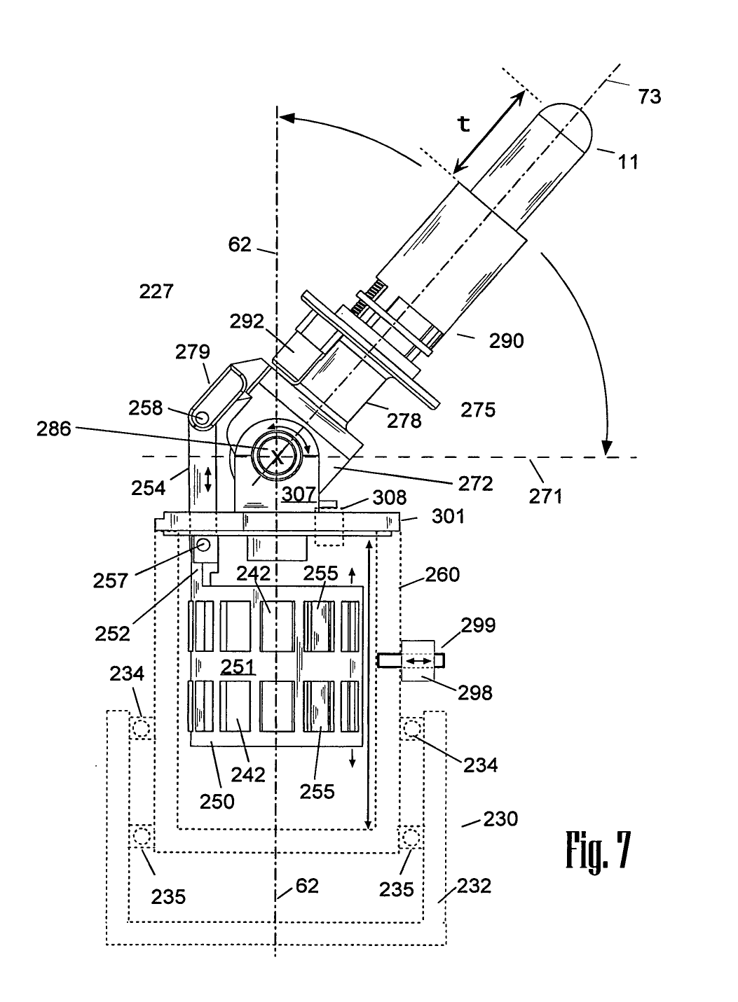

In more particular embodiments of the DTA, various specific mechanisms and structures provide the desirable attributes of a compact and modular tracking assembly, which also provides means for both (or one of) HTF exchange and electrical current exchange with the solar tracking receiver/concentrator combination. In its overall layout, in FIGS. 6-7, various particular attributes and structures enable these functions, so that the DTA provides functions of altitude and azimuth tracking motion, as well as interfacing electrical and HTF connections of the receiver tube to static connections of the external world.

To provide these functions, the DTA (227) is composed of several main components, in FIG. 6-7, comprising, (a.) a static base assembly (SBA), which SBA (230) is a supporting base of the DTA and provides demountable connection to the BMA, (b.) a rotating carriage assembly (RCA), which RCA (260) supports drive motors (267) (268) of the tracker and rotates within the static base assembly to provide azimuth tracking, (c.) a turret flange assembly (301), which provides supporting forks (bearing pillow blocks) and feed-through openings to the tilting portion of the tracker, (d.) a receiver tilt assembly (RTA), which RTA (270) includes the receiver tube and its mounting structures that tilt about axis (42), and, (e.) a shuttle assembly (250), which is disposed within the RCA, and provides mechanical means for moving the altitude (or tilt) tracking of the RTA about tilt axis (42). These five components (a-e) will be described in more detail in the present disclosure.

It is preferred that the DTA interface with the non-rotating BMTA (426) by way of a static, preferably cylindrical, base, which is a cylindrical tracker static base assembly (230) comprising a static cylindrical base structure (232). The static cylindrical base structure houses an internally rotating assembly, the rotating carriage assembly (RCA), supported by means of wide-diameter bearings, large-diameter bearings (234, 235), preferably at least two roller bearings comprising upper large-diameter roller-bearing (234) and lower large-diameter roller-bearing (235) that are in turn supported and positioned by the static cylindrical base structure (232).

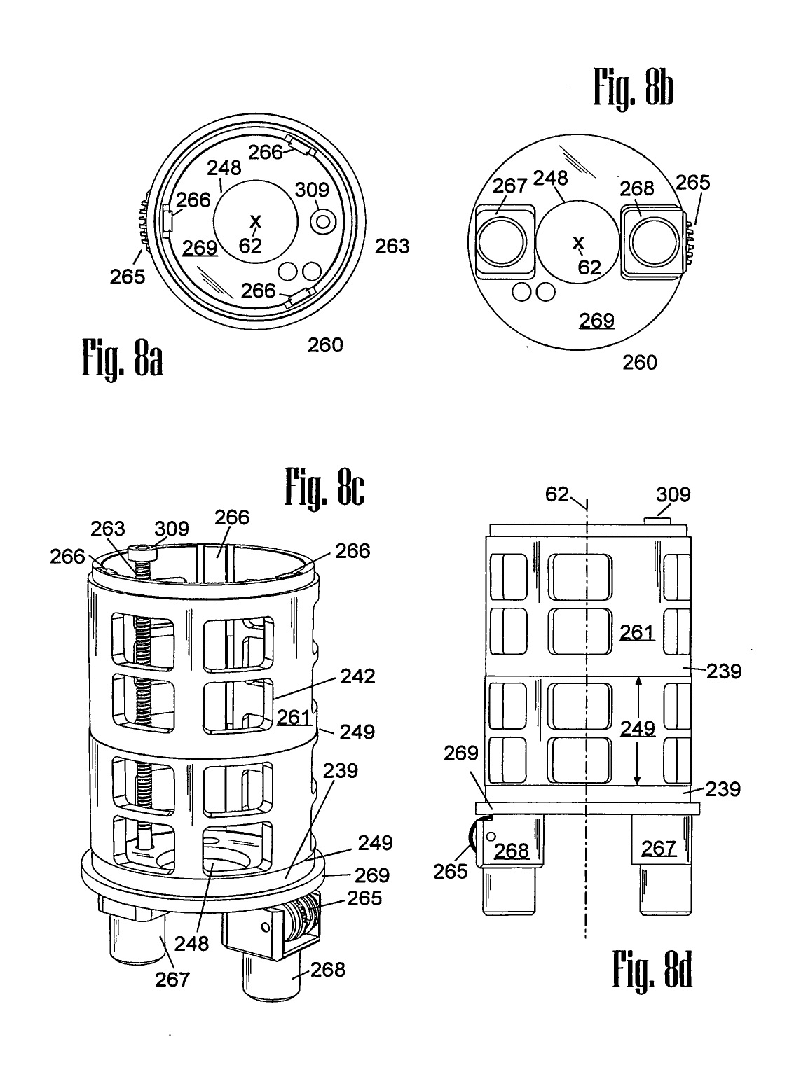

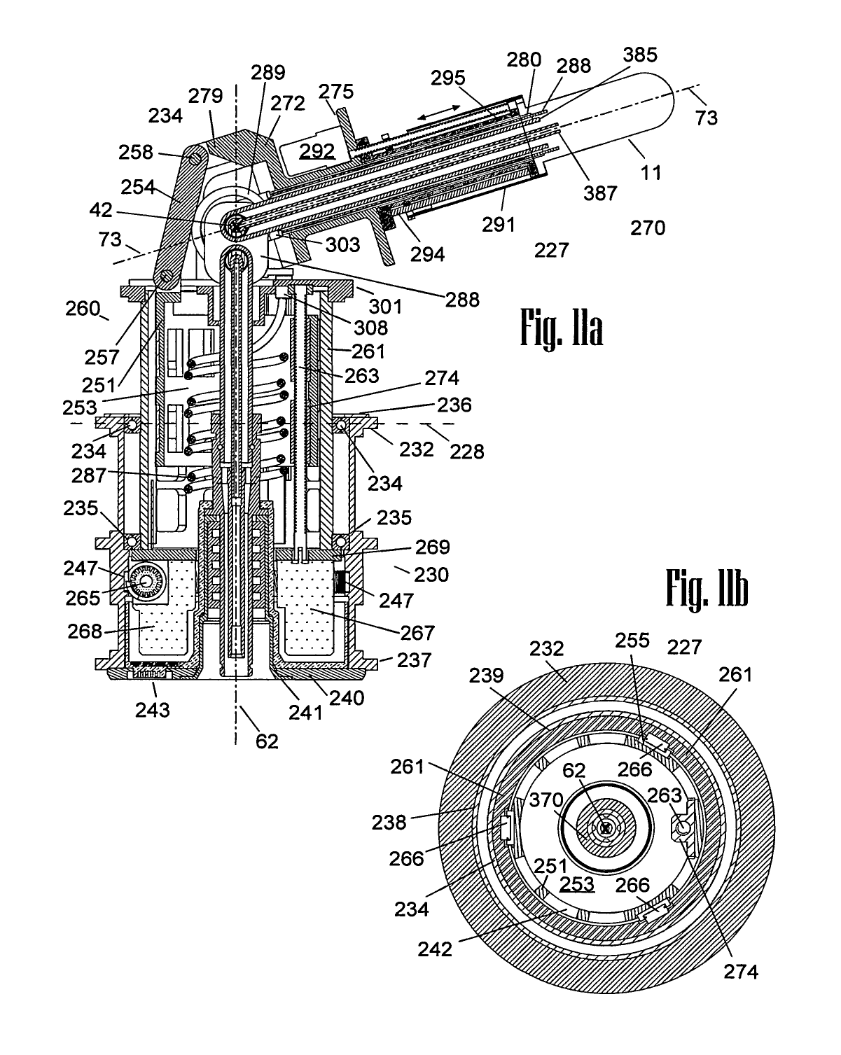

As embodied earlier, mechanical pivot/azimuth adjustment of the tracking receiver tube/concentrator combination is preferably provided by rotation the embodied rotating-carriage assembly (260), or RCA, in FIG. 6-11. The RCA is structurally supported by and including associated tracker rotating carriage tube (261), embodied particularly in FIG. 8 and FIG. 11, which provides multiple functions including provision of structural housing and guide surfaces for the tilt mechanism, as well as a linear-bearing lead screw (263), for driving tilt adjustment, is disposed so as to provide linear positioning of the shuttle tube (251) by which tilt of the receiver is provided.

The (RCA) rotating-carriage assembly (260), in FIG. 8(a-d), is further embodied to incorporate the mechanical driving mechanisms by which the 2-axis motion—tilt and pivot—are provided. In particular, in the first preferred embodiments, the drive motors, for each of the two embodied axes of motion, are preferably positioned and attached to the underside of the RCA as an integral part of the RCA.

These two motors (267) (268) are supported by and rotatable within the cylindrical tracker static base assembly is thereby provided means by which the RTA can be positioned and aligned at various azimuthal positions with respect to the SBA (230) and supporting BMA (400).

Accordingly, for driving altitude (tilt) and azimuth (pivot) motion, tracker altitude drive motor (267) and tracker azimuth/pivot drive motor (268) are preferably positioned at positions located on the RCA base-flange (269), which comprises the bottom flange of the RCA, and which is concentric to and attached to the tracker rotating carriage tube (261). These motors are preferably gear-motors of associated high torque and speeds appropriate for solar tracking. Three altitude linear bearing rails (266) that are attached to the interior walls of the tracker rotating carriage tube (261), are disposed to provide precision translation of the shuttle tube (251), which is positioned by means of the altitude linear bearing lead screw (263). The altitude linear bearing lead screw (263) is mechanically rotated through conventional means by its associated drive motor, the altitude drive motor (267).

Accordingly, azimuth (or pivot) tracking is preferably driven by the azimuth/pivot drive motor (268), wherein a tracker azimuth/pivot drive gear (worm gear) (265) is part of the mechanical interface to the pivot drive motor, and this worm gear engages a static gear structure (247) incorporated into the inner surface of the static cylindrical base structure (232), in FIGS. 6-11. The static gear structure (247) is preferably a series of grooves appropriate for a gear engaged by and rotated by a worm gear, as is common in the art of gear box and mechanical design.

In the rotating carriage tube, it is preferred that openings defined by cut-out features (242) that reduce weight and increases access to inner assembly. Similar openings defined by cut-out features (242) are preferably also integrated into the shuttle tube (251).

The rotating carriage assembly preferably incorporates a locking mechanism (298) for locking the position of altitude/tilt movement, in FIG. 7. The locking mechanism preferably comprises locking mechanism (298) that activates a locking pin (299) for the purpose of locking the linear shuttle assembly (250) so that it cannot move, and thereby locking the altitude adjustment of the DTA and attached solar concentrator (70). Preferably, the locking mechanism is disposed to lock the altitude adjustment of embodied solar tracking apparatus when the DTA and attached solar concentrator are pointed directly upwards, so as to allow wind passage under the reflecting concentrator (70) under high wind conditions.

Whereas pivot adjustment of the tracker is provided by rotation of the rotating carriage tube about pivot axis (62) within the static base, tilt motion of the embodied tracker is provided by mechanical means located within the rotating carriage tube (261) and associated RCA, in FIGS. 6-11.

The tilt (or, alternatively, altitude) adjustments of the tracker assembly are preferably provided by means of translating a linear motion into the desired tilt/altitude adjustment. This is provided by positioning of a shuttle element that is positioned along parallel linear bearing tracks, which bearing tracks preferably comprise commercially and widely available linear bearing assemblies comprising linear guide (266) and mating linear bearing unit-sleeve (255) as commonly embodied in linearly guided bearings. Such linear bearing means are well-understood in the art, and modular versions of linear bearing assemblies are provided commercially by such well-known suppliers as SKF, TKD, Thompson Inc., as well as numerous other suppliers.

Preferably the linear bearing track comprises a spaced and parallel array of linear bearing tracks, such that movement of the shuttle element is guided simultaneously by the array of linear bearing tracks. In this way, undesired mechanical play is avoided and mechanical spatial resolution is enabled by rigidity in directions other than the desired linear direction of motion. Accordingly, it is preferred that linear bearing tracks, preferably provided as separate bearing guides (266) with mating sleeves (255), or alternatively as spaced-apart bearing structures integrated into a hollow pipe (round, square, rectangular, hexagonal, triangular, or other shape), be incorporated such that at least three guiding surfaces are spaced apart from one another, such as to preferably allow a 5 centimeter clearance diameter to exist within said array of bearing guide surfaces, with, preferably, said clearance space roughly centered on the azimuthal axis (42).

The linear shuttle assembly (250) preferably incorporates linearly translating linear shuttle tube (251) and an integral link structure (252) that is integral to the shuttle tube and disposed for connection to the associated linkage arm (254). It is further preferred that an interior space (253) of shuttle tube is formed, such that this formed space is adequate to contain a portion of the wire harness, and more preferably, a flexible or otherwise rotatable portion of the wire harness; such space also preferably containing the coaxial piping of the embodied fluid transport assembly.

The mechanical coupling linkage arm (254) interconnects integral linking structure (252) of the shuttle tube to the alt-mount drive coupler (279) integral to RTA mount structure (272), wherein linkage is accordingly utilizing of ball-bearing supported axes, such axes comprising lower horizontal bearing axis (257) of linkage arm and upper horizontal bearing axis (258) of the linkage arm, in FIGS. 6-12.

While various conventional means for altitude motion of the embodied solar tracker may be incorporated into alternative embodiments of the embodied tracker, it is most preferred that altitude (or tilt) adjustments of the receiver and concentrator are provided by mechanical coupling these components to linear motion means, preferably wherein the linear motion means comprises multiple linear bearing surfaces spaced about a hollow metal tube element, in FIGS. 6-12. In its most preferred embodiments, an array of three linear bearing guides (266) are integrally attached to the interior wall of the rotating carriage tube, such that the bearing rails are equally spaced about a circle roughly corresponding to the carriage tube interior, insofar that they are disposed to provide linear guidance of the shuttle tube (251) within the interior of the carriage tube, preferably guided for motion in a direction along the central rotational axis (62).

Rigidity and stable positioning capability is provided by an extended spatial relationship between the embodied, mutually guiding, linear bearing assemblies that guide the shuttle tube up and down within the rotating-carriage assembly (260). Accordingly, the altitude-adjusting, linear bearing guide means preferably comprising linear bearing guide rails (266), are positioned at spaced intervals about the periphery of the interior of the rotating-carriage assembly (260), in FIGS. 8 & 11. The linearly translating shuttle tube is accordingly disposed to translate vertically within the rotating-carriage assembly (RCA) by means of being guided along the linear bearing guide rails, in FIGS. 7-8 & 11. A mating guide ball nut (274), preferably two, in FIG. 11, is attached to the inner surface of the shuttle tube (251) and engaged by the lead screw (263) in the conventional manner of lead-screw driven ball nut in conventional mechanical systems, so that the shuttle tube is driven along the embodied linear bearing assemblies by the embodied lead screw and gearmotor (267), to which it is coupled.

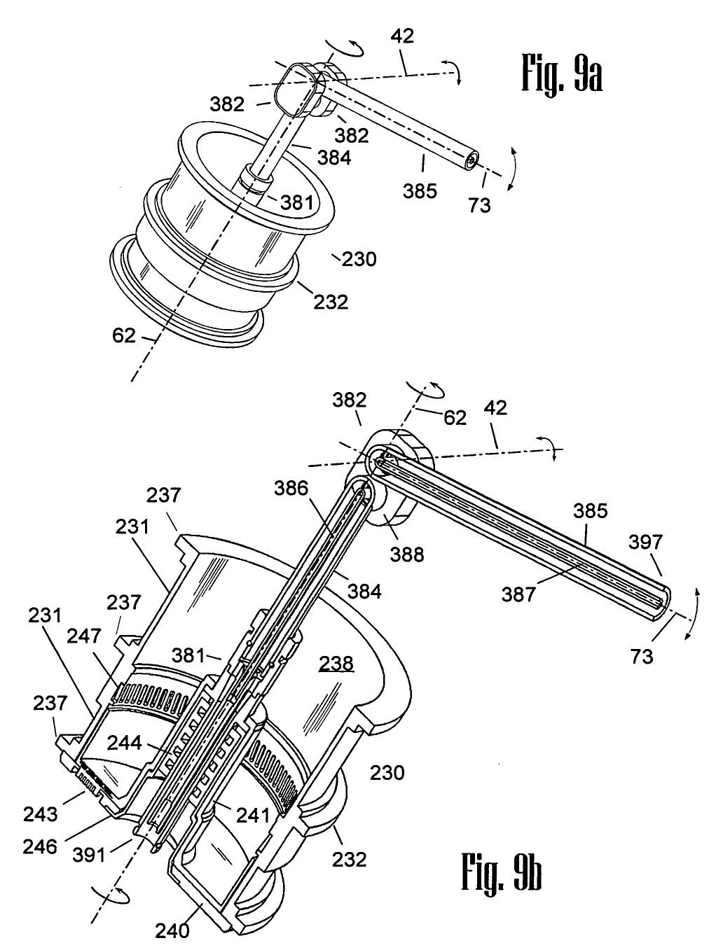

The static cylindrical base structure (232), which preferably comprises a tubular aspect, incorporates straight-wall tube sections (231) which preferably separate reinforcing structural rings providing reinforcement and outside registration surfaces (237), in FIG. 9, which enable secure registration and positioning with the receptacle of the BMA.

Accordingly, the outer static surfaces of the large-diameter bearings (234) (235) are fitted between so as to contact static bearing-contact surface (238) disposed on inner surface of the SBA tube-like structure (232) and rotating bearing-contact surfaces (239) disposed on outer surface of the RCA tube (261), thereby enabling rotation of the RCA in relation to the SBA. Raised edges for roller bearing registration edges (249) are provided on the exterior surface of the tracker rotating carriage tube (261) to provide positioning means against which the large-diameter bearings are secured. The large-diameter bearings are positioned with respect to one another by means of steps (249) formed into surface of the rotating carriage tube (261), and further clamped securely by roller bearing retainer plate (236) that is fastened to the top of static cylindrical base structure (232), in FIGS. 9-11.

A central opening feature (248) in the carriage base-flange (269) of the rotating carriage base provides an opening for clearance of the fluid-assembly sleeve enclosure (246) and static sleeve wire harness (241), which are incorporated into the static base assembly (230).

As embodied earlier, the static base assembly (SBA) incorporates a tracker static base flange (240) attached to its underside. The tracker static base flange (TSBF) provides a mounting surface means for the static portion of wire harness (241), which extends to an insulated tubular sleeve that lines the outer surface of an internal tubular structure, namely fluid-assembly sleeve enclosure (246). The sleeve enclosure is preferably a thin-walled aluminum tube having flanged ends for mounting to the TSBF at the base opposite flanged end for supporting and mounting static portion of azimuth/pivot rotating-union assembly (381), which is mounted on and fastened to a sleeve top-flange (256) integral to the aluminum sleeve enclosure (246). The static portion of wire harness (241) is an array of metallic and conductive wires or alternatively deposited metal traces, accordingly disposed for providing the function of a wire harness, namely providing electrical communication between the electrical components of the receiver assembly and electrical interconnect (243) positioned on bottom of the DTA for detachable connection of the DTA to the BMA, as embodied earlier.

The tracker assembly electrical interconnect (243), which is a multi-pin electrical connector integral to, and for connecting from, the wire harness (241), is mounted into the tracker static base flange for purpose of providing demountable electrical interconnection to the mating electrical connector incorporated into the BMR assembly. The coaxial insulator sleeve (244) is insertable into and positioned within the fluid-assembly sleeve enclosure (246), and is thereby centrally positioned to and supported by tracker static base flange (240), the insulator preferably comprising Teflon (PTFE), or alternatively a polyimide or glass-like material.

Fluid Transport Assembly (FTA), which comprises fluid transport components contacting and transporting HTF between the solar-heated receiver tube (11) and the base-mount receptacle assembly (430) of the base-mount assembly, is provided as a combination of the embodied static plumbing assembly (380) (381) (391) that interfaces to rotating assemblies configured, via seal to pivoting supply tube (384) by a preferably silicone polymeric gasket (229) of the embodied rotating union, for providing fluid to the (non-static) pivoting and tilting portions of the fluid transport assembly. The static portion of the fluid transport assembly (380) is disposed within the tracker static base assembly for interfacing to mating coaxial fluid connector of the BMA by means of male coaxial disconnect (391), and is supported by sleeve enclosure (246) top. The Fluid-Transport Assembly (FTA) of the DTA comprises an assembly of coaxial fluid carrying tubes, wherein it is preferred that HTF is supplied to the receiver tube via annular volume formed between the interior walls of the outer supply tubing (384, 385) and outer walls of the central return tubing (386, 387), whereas HTF returns from the receiver tube via the passageway provided by the interior of the central return tubing (386, 387), in FIGS. 9-11.

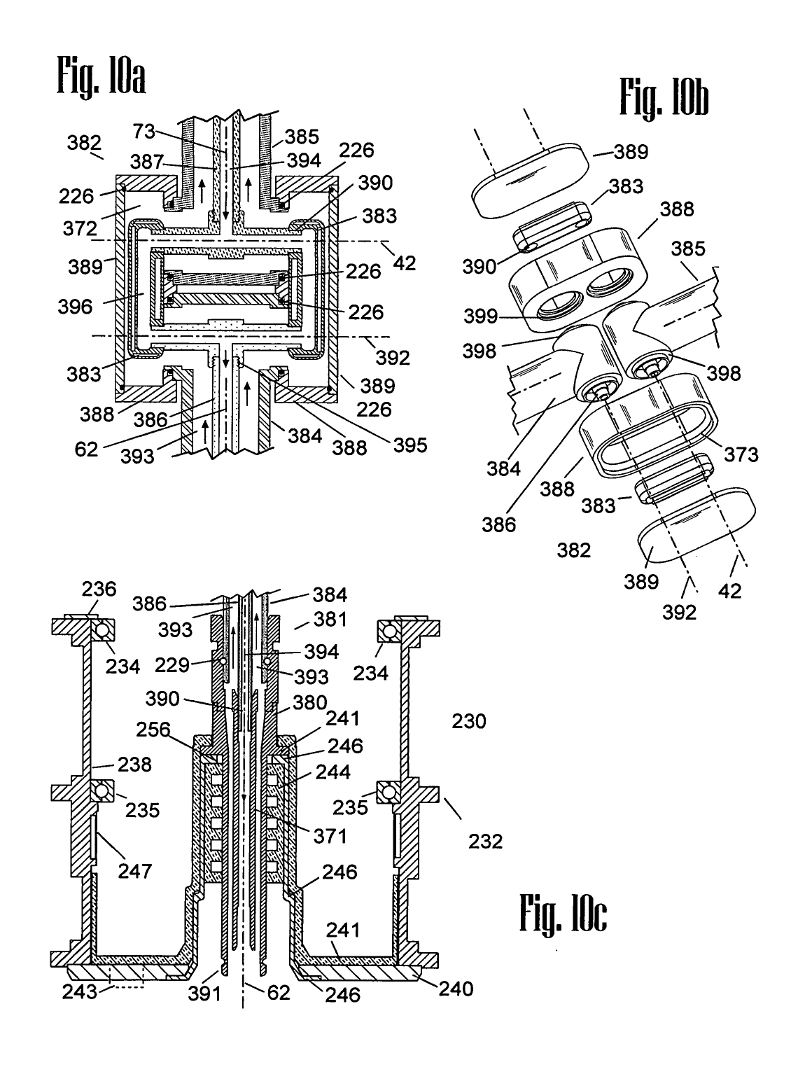

In its particular embodiments, the altitude/tilt rotating-union (alt-union) assembly (382), in FIG. 10 (a-b), comprises a union formed by coupling both the embodied inner and outer ‘T’ unions, corresponding respectively, to the return and supply ‘T’ unions, which are herein formed as a coaxial assembly. On each of two sides of the alt-union assembly, an outer alt-union rotational coupler (388) is mutually coupled to ends of each of the two embodied supply T's (384) (385) for providing passage of fluid between the two embodied T unions, wherein the couplers and mating T's each align to one of two axes (42) (392), along which the lateral segments of the coaxial ‘T’ unions become aligned. In this way, lower coaxial assembly of outer/inner ‘T’ unions (384) (386) is aligned along bottom axis (392), whereas upper coaxial assembly of outer/inner ‘T’ unions (385) (387) is aligned along upper axis (42). Sealing surfaces, T-union seal interface (398), and outer alt-union rotational coupler seal interface (399), mate so as to capture sealing o-ring (226) between these two mating and sealing surfaces for coupling together each of the two supply ‘T’ unions (385) (384). A plate-cover seal groove (373), provides a capture surface for a sealing gasket so as to seal an opposite access side comprising outward-facing side of the alt-union rotational couplers (388).

The respective access plate covers (389) covering each of the two alt-union rotational couplers (388) provides access means for insertion and access to an internal coupler (383), which is for coupling the inner tubes comprising return T-unions (386) (387). wherein the inner tilt-union rotational coupler (383) is positioned within each cavity of each alt-union, outer rotational coupler (388), the internal couplers disposed for providing coupling between respective tube-endings of the respective return ‘T’ unions (386) (387), in FIG. 10.

It is preferred that organic, polymeric seals, preferably silicone, or alternatively a Kalrez® material, be utilized for sealing between various components of the outer, supply-side, passageways of the embodied fluid transport assembly. Furthermore, a small leak from such inner seals, comprising for example 0.1% of flow therein, will have negligible effect on the performance of the embodied solar tracking apparatus.

Organic seals may also be provided for the inner, fluid returning, ‘T’ unions; however, since they are disposed within the passageway formed by the outer supply unions (384) (385), and there is an objective to increase fluid temperature above 300 C, it is more preferred that the seals of the inner return T's comprise inorganic seals, which are adequately provided by slip-fit interfaces between the sealing surfaces of the return unions (386) (387) and the inner tilt-union rotational couplers (383). Therefore, rotation of the inner tube ‘T’ fitting (386) with respect to static inner tube (371) of the static portion of the rotating union (381) is preferably accomplished by means of a slip-fit coupling seal (390), which comprises close-tolerance fit of the embodied mating tube sections, such as disclosed in previous applications by same author.

Moreover, within the DTA, the static portion of the fluid transport assembly (380), which, in FIG. 10(c), includes the static portion of azimuth/pivot rotating-union assembly (381), provides a sealed rotating union in fluid coupling of the rotating coaxial assembly comprising co-linear supply T-union (384) and internal, co-linear return T-union (386), wherein (304) (386) are thereby able to rotate with the embodied RTA and RCA, in sealed union with the static portion of the union (381), assisted by polymeric silicone seal (229), in FIGS. 10-11.

A threaded joint (395) is preferred in construction of both return T-unions (386) (387), so as to enable construction within surrounding supply unions (384-385), resulting in the preferred and embodied coaxial geometry, comprising a multidirectional and coaxial flow loop.

Accordingly, the embodied assembly of fluid supply and return plumbing provides an annular supply passageway (393), and interior return passageway (394) (396), which together provide supply and return passageways for exchange of HTF (heat transfer fluid) between the embodied receiver tube and an external plumbing circuit preferably including an HTF-powered load, such as sorption-based air-conditioning.

The receiver tilt assembly (270) is part of the DTA tracking assembly (227), wherein tilt motion of the RTA is provided by means of rotation about tilt axis (42). The tilt/altitude axis (42), during azimuth motion about the pivot axis (62), translates through altitude axis translation plane (271), which accordingly contains this tilt axis.

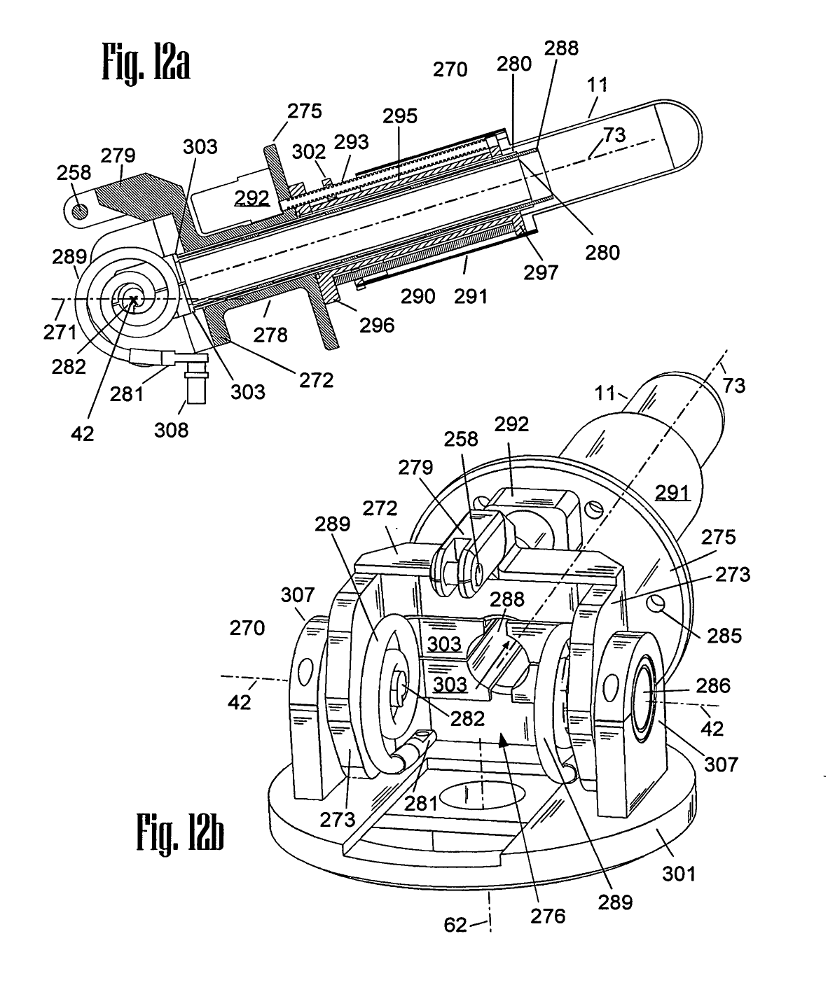

The receiver tilt assembly (RTA) is constructed as an assembly primarily supported by structural support member, the RTA mounting structure (272), which is supported at its tilt axis by bearing-supported tilt axle (286). Further embodied is a mounting fork (273) formed as integral to the RTA mounting structure (272), comprises structural members that form a rigid structural housing, thereby forming alt-mount inner recess/cavity (276), wherein resides altitude rotating union (382) and wire spiral (289), as well as providing rigid mount surfaces for integral tilt axle (286), which rotates inside the supporting fork comprising turret flange pillow blocks (307), in FIGS. 11-12. Accordingly and preferably, figurative intersection of optic axis (73) and azimuthal axis (62) is substantially located within the formed recess (276) containing the tilt rotating-union-assembly (382).

It is further embodied that the embodied RTA's mounting structure (272) includes structural features including a mount structure extension tube (278), which extends to a concentrator mount flange (275), which, as comprising cylindrical aspects, together share the indicated central axis (73) in the assembled solar tracker. The receiver tilt assembly (RTA) mounting structure (272) preferably incorporates mechanical extension comprising an integral altitude-linkage coupler (279), which provides axle (258) and according rotational linkage to the shuttle assembly so at to provide altitude adjustment of the RTA about the tilt axis (42).

A bolt pattern (285) formed in the concentrator-mounting flange (275) provides means for fastening to and supporting the CCC (70) at its mounting base (131), wherein mating bolt-hole pattern is similarly disposed for purpose of mounting to the tracker.

Various interconnection means for both electrical power and electrical signal communication are described in the prior art, and readily utilized in conjunction with the present solar tracking assembly. In particular, while specific interconnection means are described in conjunction with the receiver tube, in aforementioned patent applications, it will be understood by those skilled in the art that electrical interconnection between receiver tube and tracker can be configured in a variety of ways. The present embodiments comprise means for extending multiple electrical conductors to the receiver tube, so that power and signal connections of the receiver tube may be interfaced to these conductors.

Accordingly, electrical conductors of the present invention comprise means for transporting electrical currents between the receiver tube region and outside hook-ups adjacent the embodied solar tracker apparatus. Whereas electrical conductors within the BMA may comprise conventional conduit and interconnects standard to the art of power electronics, the DTA incorporates means for providing electrical interconnection between moving electrical interfaces of the receiver tube/CCC and stationary interfaces of the BMA. As further embodied, multiple conductors of the DTA are provided as a wire harness having lower static regions and upper, non-static, sections. Connected to and extending above the static portion (241) of the DTA wire harness, is a flexible wire harness (287) providing rotational flexure in the azimuthal plane. The flexible wire harness (287) comprises a multi-conductor coil, and is substantially contained within the rotating carriage assembly, thereby allowing a reliable electrical connection between the static and azimuthally rotating components of the DTA with flexure and mechanical compliance of the flexible wire harness (287) allowing rotation of its upper contacts, located at the turret flange (301), around central axis of its helical coil path, which is coincident with azimuthal axis (62), in FIGS. 11-12.

The flexible wire harness (287) thereby provides means for reliable electrical connection between the static wire harness (241) and the azimuthally rotating turret flange (301), where flange-mounted connector feed-through (308) is attached and provides electrical feed-through interconnection of the flexible wire harness (287) to a flexible wire spiral (289) located above the turret flange and compliant to tilt/altitude motion of the tracking receiver assembly (RTA).

The wire spiral (289) is accordingly a planar coil that flexes rotationally about its axis, coincident to tilt axis (42), so that its integral and central electrical fastener (282), located at tilt axis (42), is able to rotate with respect to the wire-spiral static fastener (281) of the wire spiral, which is positioned at and fastened to insulated electrical feed-through (308) passing though the turret flange (301).

Electrical connection between tilting and non-tilting components of the embodied DTA may alternatively be accomplished by various rotating electrical unions of the prior art, such as by those manufactured by Mercotac or similar manufacturers of rotating electrical contacts. However, for low cost and reliability, it is preferred that a flexible coiled wire connectors be used in multiple sections for the embodied rotating electrical connections.

In extending electrical conductors of the DTA from spiral-wire coil (289) of the RTA, the wire spiral fastener (282), in FIG. 6 and FIG. 12, contacts a tubular array of conductors (288) that extends multiple conduction paths from the spiral fastener up through the extension nipple (295) where multi-conductor electrical interconnection to the receiver tube is readily configured in accordance with the specific tube utilized. The tubular array of conductors is preferably disposed as an insulated, sleeve-like assembly of conductors that is insertable into and slides against the interior surfaces of the tubular interior of the receiver assembly mounting structure (272) and extension nipple (295); and, accordingly such tubular array is inserted along and coaxial to the RTA axis (73), which is identical to the optic axis (73) of the resultant solar tracker.

The tubular conductor array (288) is electrically insulated from both its concentric tubular housing comprising the receiver assembly mounting structure (272) and extension nipple (295), as well as electrically insulated from metallic surfaces of the coaxial fluid transport pipes (385) extending within the tubular conductor array. Accordingly it is preferred that tubular insulation sheaths (280) line both interior and exterior surface of the tubular conductor array (288), in FIG. 12.

Interconnection between each side of the tubular conductor array (288) and respective spiral wire fastener (282) located on each side of the optic axis (73) and centered on the tilt axis (42), is provided by conductive metal straps (303) that are integral to the tubular conductor array and line the interior of the RTA inner cavity (276).

Accordingly, in the present embodiment, wire spiral turret flange fastener (281) provides an insulating feed-through for providing electrical communication between the flexible wire spiral (289) and storage flexible wire harness (287), so that electrical current may be exchanged between the receiver tube and the BMA.

The rotating carriage tube (261) preferably is fitted with a fasten-able lid comprising alt-mount turret flange (301), which comprises a steel, or alternatively, aluminum, flange, having opening for passage of altitude linkage assembly (254) (252) and additionally a mounting surface for the mount fork (307) comprising pillow block bearings (307) that support the RTA. The alt-mount mount turret flange (301) also provides pass-through holes for mounting of insulated, electrical feed-through connections (308) and coaxial fluid plumping (284) (286). The alt-mount turret flange (301) also provides fastening surface for altitude drive screw top-bushing (309) thereby providing mechanical support and positioning of the rotating drive-screw (263) at its end opposite that end coupled through the RCA bottom flange (269).

For support of the embodied RTA and providing rotation about tilt axis (42), it is preferred such function be provided by a turret mounting fork (307), preferably comprising bearing pillow blocks, which is rigidly fastened to alt-mount mount turret flange, such mounting fork essentially comprising two supporting bearing assemblies comprising bearing pillow blocks, mutually aligned so as to support coaxial RTA structural axle (286) integral to RTA mounting structure (272), so as to rotate about tilt axis (42), in FIGS. 11-12.

In accordance with disclosed embodiments of copending patent applications by same author, a heat shield assembly (290) is preferably be utilized for protecting the receiver tube immediately prior to and after operation of the solar tracking apparatus. Accordingly, a heat shield (291) is utilized in the present embodiments for such purposes. Linear movement of the heat-shield is preferably accomplished by means of heat shield drive motor (292), which drives a heat shield lead screw (293) and its mating insert/nut comprising heat-shield threaded drive nut (302) rigidly fastened to heat shield for linear motion thereof, this assembly thereby providing a translation mechanism for moving the heat-shield back and forth between a position that covers the receiver tube (11), and a stow position covering the extension nipple (295).

The heat shield mount extension nipple (295) is an extension nipple providing multiple functions including means for support and storage of the heat shield assembly, in addition to provided the required clearance between the CCC base mount (131) and the desired location of the receiver tube (11) along the central optical axis (73), which will be precisely determined by the local geography and particular CCC utilized.

As an interconnecting nipple, the extension nipple (295) accordingly incorporates opposing flanges comprising extension nipple lower flange (296) and extension nipple upper flange (297). Preferably, heat shield guide bars (294) are utilized to provide reliable guidance of the heat-shield in a well-defined linear manner, wherein the flanges provide function of supporting the guide bars (294) and lead screw (293) in the heat shield assembly. Alternatively, the heat-shield may be spring-loaded to allow movement of the heat-shield quickly for purpose of quickly covering the receiver tube when spring tension is released, such as by release triggered by an electrical interlock, due to such events as misalignment, malfunction, wind/weather conditions, overheating of various components such as receiver, photovoltaics, or HTF, or other interlock trigger mechanisms.

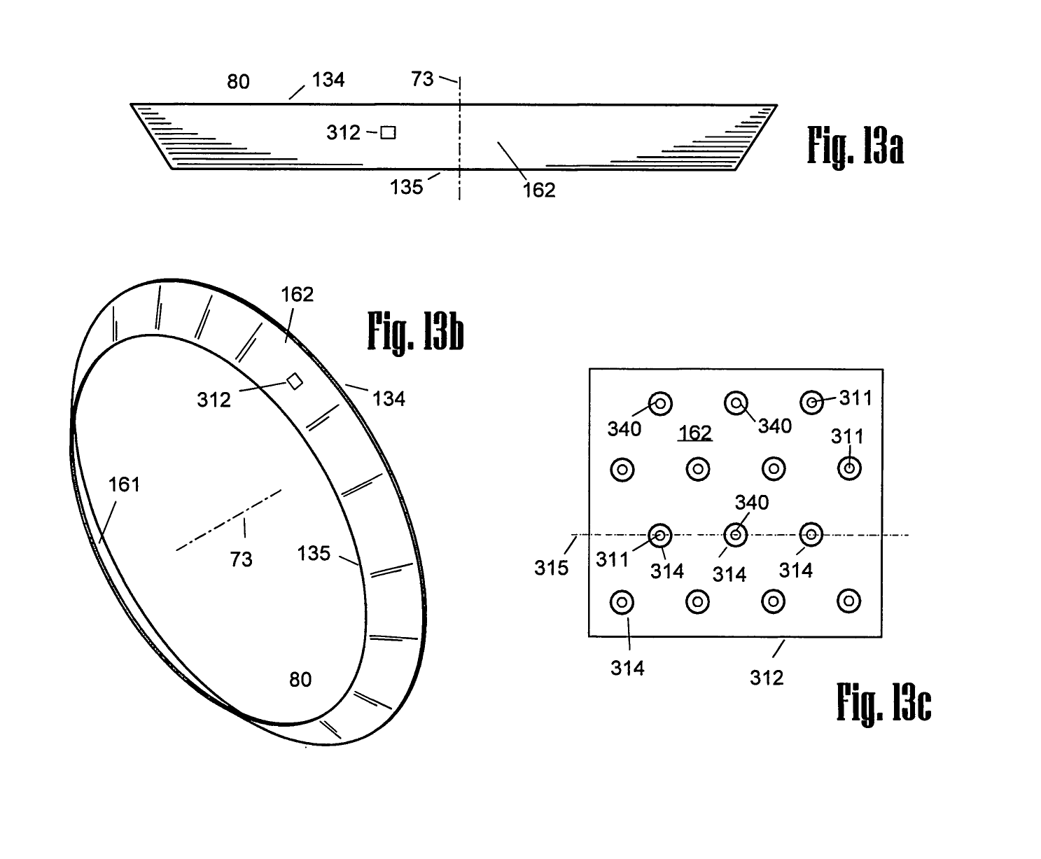

As in the previous patent applications by same applicant, the embodied CCC utilizes a stackable sequence of discrete frustum-shaped structures (80), in FIG. 13(a-b), a frustum having a first, preferably aluminum, surface layer (161) providing a desirable solar reflectance, and second surface layer (162) that preferably also comprises a rolled metal sheet (or foil); also, terminating edge structures are provided as both upper edge structure (134) and lower edge structure (135), as embodied in the related patent applications.

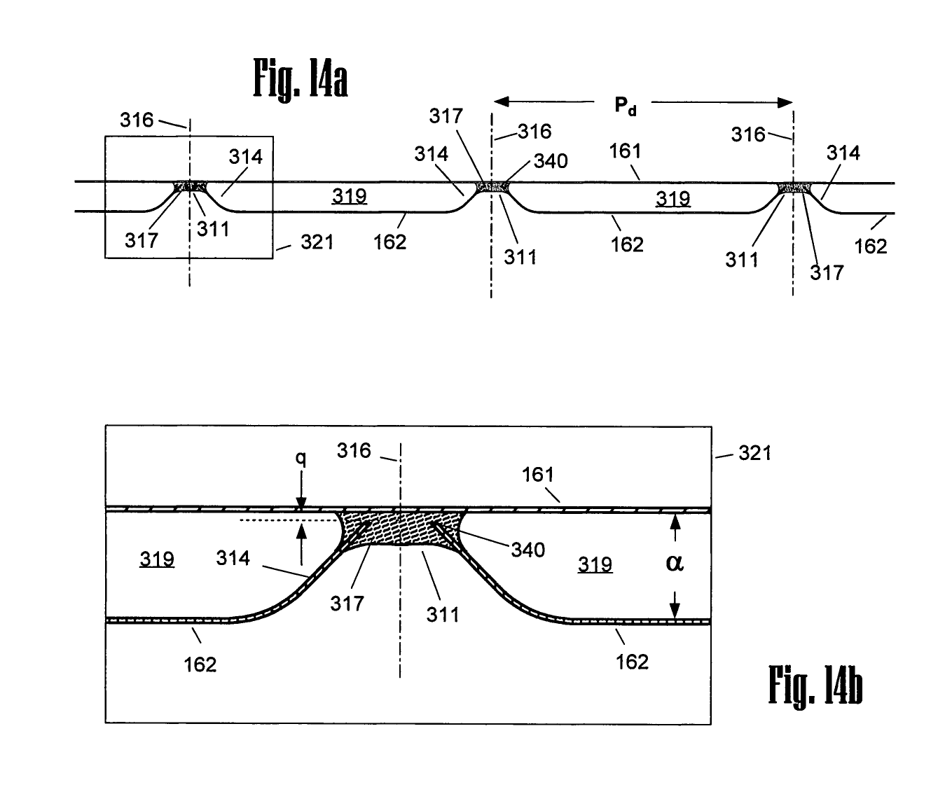

In an alternative preferred embodiment of the specified frustum structures (80), frustum structure and methods of forming are disclosed for providing the preferred hollow-core, concentrically stack-able, frustum structure. In FIG. 13c, the double-walled frustum (80) is fabricated so as to incorporate an array, preferably periodic, of indented deformations (314) in the outer wall (162) of the embodied double-walled frustum structure. Such indented deformations more preferably comprise dimpled deformations formed by a dimpling method, such that each indented deformation preferably comprises a roughly circular cone-shape deformation having a roughly flattened, or truncated, apex of said cone-shape, accordingly having a central axis of the dimple structures circular symmetry (316) in FIG. 14. More particularly, it is preferred that the cone-shape of the indented deformation be truncated by means of forming a dimple opening (311) at the apex of the cone-shaped deformation, thereby forming a truncated, flattened aspect at the top of the apex, said opening defined by the according truncated cone-shape with a central hole edge, the hole preferably formed by a hole-punch operation.

In the present preferred embodiment, the second rolled-metal segment of sheet metal (162), having formed in it the formed array of cone-shaped deformations, is aligned adjacent the first inner sheet metal layer (161) so that the truncated apex structure (340) of each deformation structure is disposed adjacent the back-side (inner, non-reflecting side) of the first flexible sheet material (161). In this way, the truncated cone-shaped deformations provide a spacing structure that defines the dimension of space-gap existing between first and second material layers (161, 162), in FIGS. 13-14. In the present preferred embodiments, it is preferred that the clearance between the first inner material (161) and the truncated apex structure (340) defining a hole-structure, preferably comprise a distance between 0-3 millimeters. It is additionally preferred that each truncated apex be adhered to the first inner layer (161) by means of an organic resin material (317) disposed so as to encapsulate the truncated apex structure and fill the opening defined by the apex structure, in FIG. 14. In addition, the resin deposit (317) is adhered to the inside surface of the first sheet metal layer (161), thereby forming a structural union between the inner layer (161) and outer layer (162) of the embodied frustum structure (80). It is preferred that the spacing between first and second layers (161, 162) be provided in the same range indicated in previous disclosed embodiments.

The resin deposit (317) preferably comprises a resin having mechanical properties appropriate for high strength and limited flexibility, such as outline for adhesive resins appropriate for formation of aluminum hexagonal honeycomb panels and similar structures, e.g., phenolic resins, epoxies, preformed adhesives, silicones, etc, and is preferably an epoxy resin. Dimple deformations (314) are preferably arranged in periodic array, such that a straight intersecting centerline (315) will intersect a row of the dimple structures, in FIG. 13(c).

Clearance distance, q, in FIG. 14, between the inner edge (340) defining the dimple opening (311) of the truncated cone-like indentation (314) and the first layer (161) of the frustum is preferably within a range of distances, such that, 0 mm≦q≦3 mm, though the distance, q, between the dimple deformation (314) and first frustum layer (161) may be greater than this without departing from the invention. It is accordingly embodied that there also be a clearance space (319) between first and second layer, in FIG. 14, or alternatively, inner and outer layer, of the embodied frustum (80). In particular, a spacing, α, is provided between first layer (161) and second layer (162) of the frustum structure. It is preferred that this spacing be that specified in the aforementioned patent applications disclosing the embodied frustum structure. In the present embodiment, the clearance, α, is more preferably provided within a range such that, 1 millimeter (mm)≦α≦6 mm.

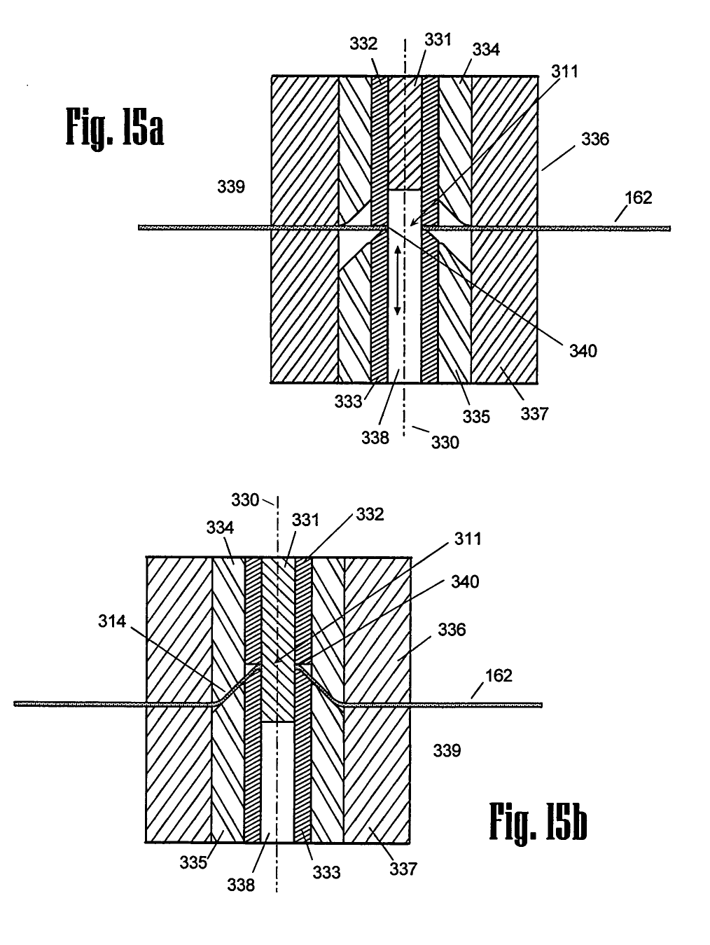

Formation of the preferred cone-shaped indented deformations (314) of the present embodiment is preferably executed by means of a stamping press, in FIG. 15(a-b), of the compound variety, such that multiple sequenced stages of the cone-shaped deformation process may be used to provide a periodic array of hundreds of such truncated and cone-shaped deformations, the array of dimple structures formed into a single segment of rolled metal sheet, wherein a multitude of such segments may then be utilized to form the second layer of the embodied frustum structure (80).

Each stamping press assembly providing an embodied dimple structure is comprising a concentric assembly of cylindrical punch and/or clamp elements, consistent with the circular shape of the various features of the dimple structure, and, accordingly, this concentric array of cylindrical elements comprising the each individual stamping assembly, may be designated a center axis of the dimple press (330). From center to outer portions of the dimple press assembly, elements for stamping and/or punching are essentially in a slip-fit according to the conventional art of sheet metal forming.

More particularly, the stamping process utilizes a multitude of dimple-forming press-punch structures, each punch-press structure incorporating both means for punching the embodied circular opening (311), as well as means for forming the preferred cone-shaped dimple shape, in FIG. 15(a-b).

In particular, a punch-press tool of the preferred embodiments incorporates a concentric array of punch-press elements that enable a sequence of punch-press operations resulting in the desired truncated cone-shape deformation, in FIG. 15(a-b). In accordance with the present preferred embodiments, the punch press includes a central punch assembly for forming the punched hole (311) comprising the embodied dimple opening, wherein the punch element (331) punch cylinder/rod passes through central punch cavity (338) formed by punch casing, which is the tapered punch/clamp element (332) that enables simultaneous clamping by the tapered punch/clamp element (332) and counter-element (333), and punching of hole by (331) punch cylinder/rod. The tapered punch/clamp element (332) is tapered so that it also performs a second subsequent extrusion function as part of the subsequent dimple-wall forming operation, wherein outer concentric tubular dimple press element (334) and opposing tubular dimple-press counter-press element (335) perform the dimple-wall formation step, in FIG. 15(b), wherein these elements combine with the tapered punch/clamp element (332) and counter-element (333), which are all aligned and displaced so as to form the conical shape of the desired cone-shaped deformation (314).

External to the embodied concentric array of stamping elements is a casing comprising, in the usual manner of sheet metal stamping, a press-punch clamp body (336) and press-punch opposing clamp body (337), which, as is conventional in stamping equipment, are separable to allow passage of material between the opposing punch/press elements for sequential stamping. In accordance with the circular geometry of the embodied dimple, or cone-shaped deformation (314), the embodied press elements have an accordingly circular geometry about the central axis (330), whereas, such press/punch means will be incorporated as a parallel array of many such assemblies in the scaled and full-size punch-press machinery utilized.

In the present embodiment, a flexible bellows cover (414) is preferably utilized so as to protect the DTA (227) from out-doors environmental conditions. Accordingly, the bellows cover preferably interconnects the base structure (131) of the embodied CCC (70) to the base-mount tube (410) at the tubes outer surface near its top edge (437). The flexible bellows is preferably composed of a polymer-coated fabric, similar to those specified for the tension-tent material, though other polymer materials and metallic materials may be appropriately used, as commonly practiced in the bellows interconnects used in protection and operation of various industrial equipment. Since the exact length of the RTA mounting structure can vary with precise CCC utilized, the bellows may also differ in its precise dimensions, as will be understood by those skilled in the art.

The base mount assembly is particularly advantageous in utilization on an architectural roof structure (404), since construction of the base-mount assembly provides a readily deployable apparatus that may be secured to the roof with relatively little tie-down requirements, as well as a large surface area for load spreading across roofs of limited strength.

Whereas various tensioning means are capable of maintaining the CCC in aligned and assemble state of operation, in the present preferred embodiment, a conformal tensioned CCC-tensioning fabric cover (342) is utilized, which forms a water tight covering over the entire back surface of the CCC.

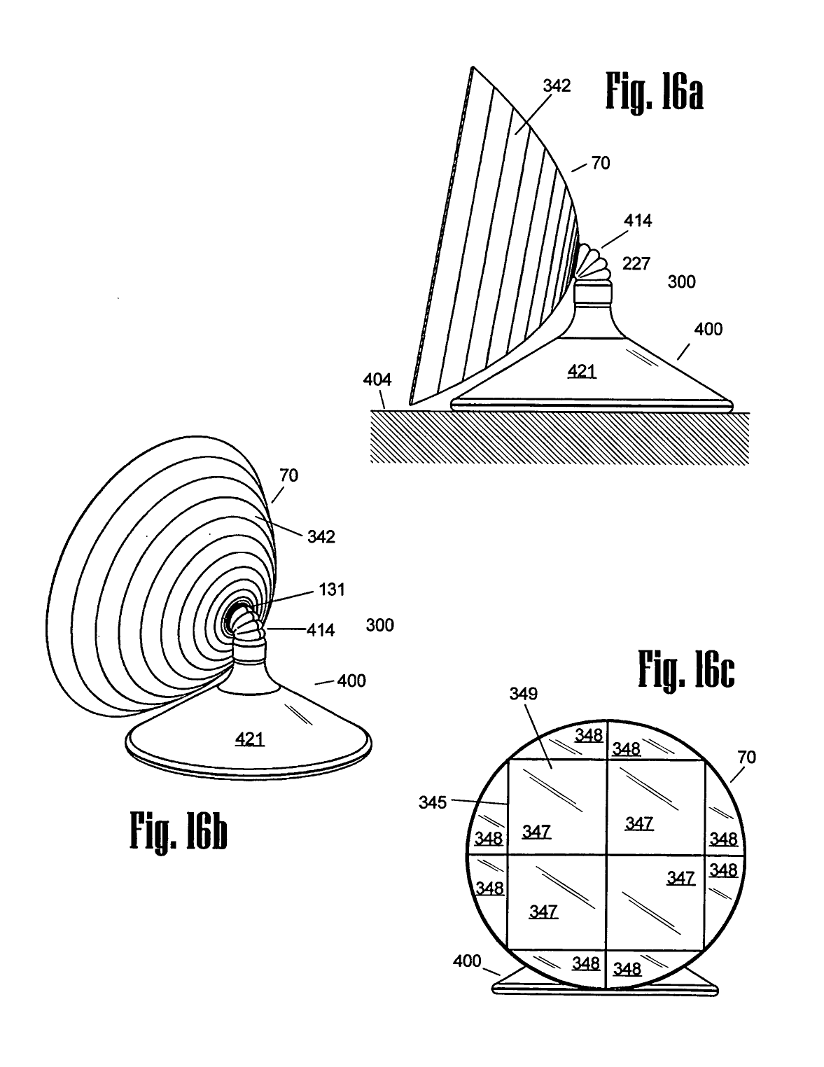

As embodied in previous disclosures, it is preferred that a glass-window covering be provided to cover the opening of the CCC, adjacent to its top rim (194) and peripheral to its largest frustum. In the present preferred embodiment, the covering comprises a sectioned window comprising two distinct shapes, namely a front window square section (347) is square in its planar dimensions, and a front window curved section (348) that has one curved edge. In particular, the square window section is made as a rectilinear shape, preferably rectangular, and more preferably a square shape in its planar dimensions. The curved section is accordingly comprising a curved shape in its planar dimension, characterized by the incorporation of two edges having a rectilinear, 90-degree relationship, such that a square corner is provided for aligning against adjacent square window sections (347), whereas the curved sections additionally provide a curved edge that is roughly equivalent to the outer perimeter (194) of the CCC, in FIG. 16(c). In this way, the front window assembly (349) comprises two distinct shapes in its sectioned window segments, and a complete window covering is disposed to seal the opening of the CCC, the complete window covering comprising two primary segment shapes.

With regards to the assembled CCC incorporated into the embodied solar tracking assembly (300), in FIG. 16, a CCC optic (70) may be provided as embodied in previous aforementioned patent applications directed to this assembly, wherein the according concentric array of frustum structures (80) are held by tensioned straps. More preferably, in the present preferred embodiments, these tensioned straps may be incorporated into a conformal covering comprising tensioned fabric cover (342), which is conformal to the outer surface of the embodied CCC for holding the stacked sequence of frustum structures (80), under compressive force commensurate to the compressive force exerted by the tensioned fabric cover, in a manner dictated by Newtonian mechanics. The embodied tensioned fabric cover (342) is stretched over the outer surface of the CCC and be tensioned between the fastening means disposed at the base structure (131) and the top-edge perimeter of the CCC structure, similarly to previously disclosed tensioning means for such strapping methods disclosed in the aforementioned patent applications. The embodied tensioned fabric cover (342) preferably comprises fabrics identical to those described for the tension tent coverings (421).

Window-glass seam structures (345) of the window assembly are preferably provided with sealing means comprising gasket seals, the seam structures preferably comprising aluminum channel framing commonly used for window framing.

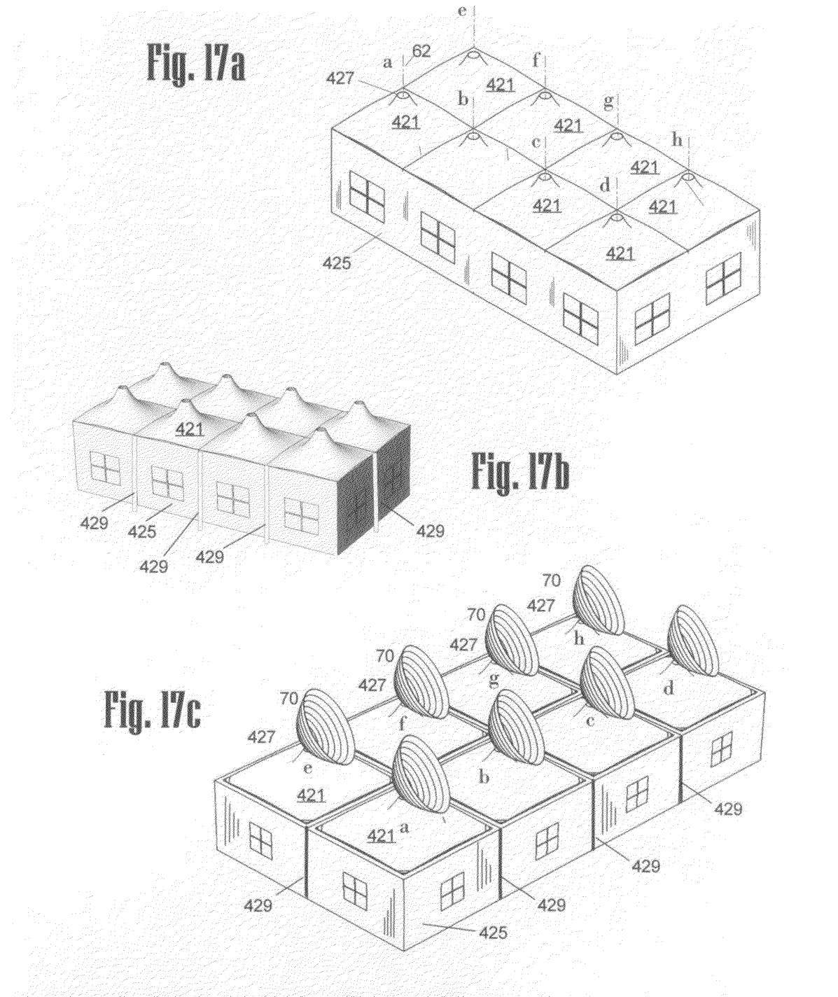

The embodied solar apparatus may be utilized in any appropriate location for harvesting sunlight. In-particular, in accordance with a further-preferred embodiment, in FIG. 17(a-c), the base and footprint need not have a circular profile, and may comprise any of a number of shapes without departing from the scope or spirit of the inventive matter disclosed herein. For example, hexagonal, trapezoidal, square, hexagonal, etc, base-mount assembly shapes may be utilized. In particular, in an alternative preferred embodiment, in FIG. 17(a-c), the preferred tension-tent structure of the previous embodiments is utilized as a roof-cover wherein the tension-tent coverings of multiple tracking assemblies (427) are adjoining to form a continuous roof covering for architectural purposes. Accordingly the tension-tent structures are suitably disposed so as to provide weather protection to both the underlying-support structures of multiple CCC's (70), as well as to an architectural structure underlying the multiple CCC's.

In the present alternative embodiment, an architectural roof structure, suitable for protective cover of a architectural building structure (425), is formed by joining or otherwise forming tension-tent coverings (421) required for multiple solar tracking apparatus of the preferred embodiments, wherein alternate shapes are given to the tent covering component so as to enable suitable joining methods between each peaked tension-tent corresponding to a separate tracking concentrator assembly. For example, eight solar tracking assemblies, with corresponding azimuth axes (a, b, c, d, e, f, g, and h), in FIG. 17, are positioned in a regular grid array, so that the corresponding array tension-tent covering (421) for each respective tracking assembly is formed in a rectangular, preferably square, shape that enables edges of each respective tent covering (421) to be connected into a substantially continuous, water-tight, roof covering. The same approach may be utilized with hexagonal, triangular, or any other shaped tension-tent covering that provides a correspondingly coordinated placement of tracker assemblies (hexagonal, cubic, etc).

Roof coverings formed in the embodied manner need not be a continuous tent, or textile, covering, since the border-region between each tension-tent cover may comprise an interconnecting walk-way, solid roofing panel, or the like; wherein it is preferred that such tension tent structure peripheral region (424) provide a water proof seam with the adjacent tension-tent cover (421).

Roof securing means (429) are utilized to secure the embodied tension tent roof to the underlying architectural structure, wherein such securing means preferably comprise straps made from similar material as the tension tent covering. Alternatively the securing means may include clamping devices or rigid supports that preferably attach to the underlying building or its adjacent-surfaces.

The present invention, comprising the embodied solar tracking assembly (300), its embodied sub-assemblies, and preferred alternative embodiments including the integrated roof covering, in FIG. 17, are intended for use in all applications previously described in the aforementioned and related patent applications. As such, applications are preferably those of combined-heat-and-power resulting from integration of multi junction photovoltaics (MJPV) using active cooling by a HTF, combined within the embodied receiver tube (11), as previously disclosed. Another preferred embodiment utilizes the present invention for use in photocatalytic applications, preferably utilizing thin film solid oxide electrolyzers, as particularly pointed out in the related applications.

With regard to solar receiver tubes utilized in the conjunction with the previously disclosed tracking apparatus and multi-frustum optical concentrator, various embodiments are previously disclosed in aforementioned disclosures by same applicant. In a further embodiment of such receiver tubes, the present invention provides a modular, demountable receiver-tube assembly for use with the described multi-frustum optic, and which it is accordingly adapted to certain preferred embodiments of the inventive tracking device.

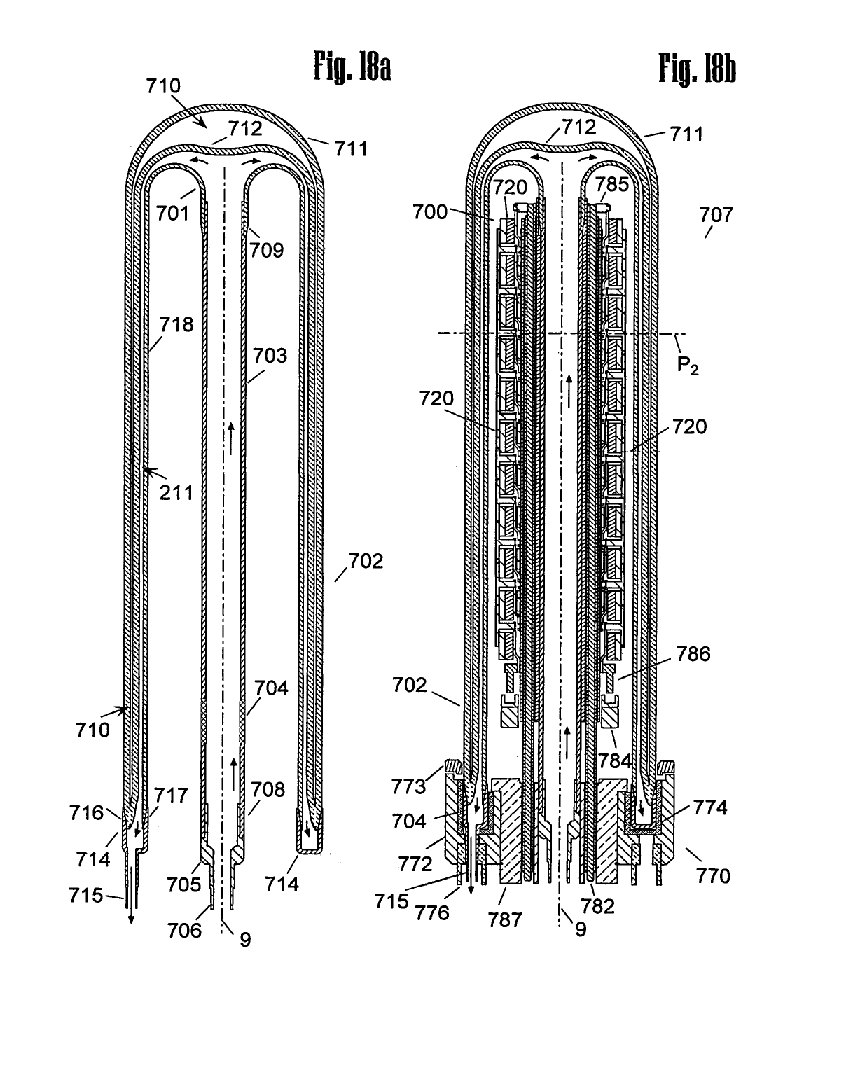

In its first preferred embodiment of a modular demountable ST-CPV receiver tube (707), the housing of the receiver assembly comprises a sealed-glass tube assembly (702) (or, “SGTA”), which preferably provides the desired annular arrangement of inner and outer HTF passageways, in FIG. 18a, wherein all features symmetrical about central axis (9) are accordingly of circular symmetry, and comprise a tubular assembly. The sealed glass tube assembly (702) is preferably constructed by means of glass-metal seals that interconnect the embodied glass components of the SGTA (702) to its metal termination structures that provide interconnection to supply and return connections of the heat transfer fluid for supplying and removing such HTF to and from the glass tube assembly. An insulating vacuum space (710) is created between glass outer tube (711) and glass inner tube (712), whereas a HTF flow space is formed interior to the vacuum space by a third, innermost glass tubular structure, namely flow-cavity liner tube (718), the three tubular glass surfaces accordingly being cylindrical tubes with coincident central axis (9).

Supply of HTF is preferably provided through the center of the glass tube assembly by means of central metallic tube (703) that is accordingly adapted to central tubular portion (701) of the flow-cavity liner tube (718) by means of upper glass-metal seal (709), in FIG. 18a. The central tube of the glass-tube assembly is terminated at its lower end by a quick-disconnect type connector (705), which is disposed so as to be demount-ably connected to female quick-disconnect (806) of the receptacle module (800) embodied later. The flow-cavity liner tube (718) is also transparent for transmitting solar radiation to the MJPV arrays disposed within the SGTA interior. The glass components of the embodied SGTA are preferably composed of a fused silica glass, though any other appropriately transmitting materials can be used. Accordingly, an elongate annular space is formed between the central metallic tube (703) and the outer tubular sidewalls of the flow-cavity liner tube (718), wherein within this space is disposed a core-insert assembly (700), or “CIA”, which incorporates the photovoltaic arrays, in FIG. 18b.

Mechanical protection of the upper glass-metal seal (709) is preferably enabled transversely by means of both support by the insulating plug (787) of the support-base (770) and conductor assembly (780), whereas it is preferably enabled longitudinally, along central axis (9), by means of relatively thinned hydro-formed bellows section (704) formed into the central tube, which is preferably of diameter equal to or smaller than that of the remaining central metallic tube (703).

Heat transfer fluid entering into the central copper tube (703) of the SGTA will flow through the SGTA's annular fluid path (211) to exit from a metal trough fluid connector (715). The SGTA incorporates a base component that terminates and seals together the glass outer-tube (711) and the inner flow-cavity liner tube (718), in FIG. 18a-b, wherein the base component is an annular metal piece having a U-shaped cross-section, and disposed for collecting the HTF exiting from the outer annular flow space (211), where such annular metal piece comprises an annular metal trough (714), wherein either side of the U-shaped cross-section is terminated at its upper edge by a glass-metal seal. The metal trough collector is sealed to the glass outer-tube (711) and the inner flow-cavity liner tube (718) by means of glass metal seals, namely outer glass-metal seal (716) seals the glass outer-tube (711) to the outer edge of the annular metal trough; and, inner glass-metal seal (717) seals the flow-cavity liner tube (718) to the inner edge of the annular metal trough. The trough incorporates one, or alternatively, more than one, metal trough fluid connector (715) on its bottom side for interconnecting and providing return fluid flow to the receptacle module that interfaces to the embodied receiver tube module (707). In certain alternative embodiments that encounter only relatively law temperatures, it will be possible to substitute the metal components of the SGTA with high-temperature polymers such as silicones and PTFE, in which alternative case, the glass-metal seals would not be required.

In its preferred embodiments, the inventive receiver module incorporates and provides means for utilizing an integral assembly of linear photovoltaic arrays, which comprises a plurality of close-packed, linear insert assemblies (720) positioned in a circular radial pattern to face outwardly from a cylindrical support structure, which together form the core-insert assembly (700). The resulting integral assembly also provides means for connection to a heat transfer fluid (HTF) supply and return passageways of an HTF circuit, in accordance with earlier embodiments incorporating particulate/micro/nano fluidics as solar absorbers, as well as interconnection means to an electrical circuit for obtaining useful power from the integrated photovoltaic arrays.

In its first preferred embodiment, the linear insert assembly (720) comprises a number of pre-assembled sub-assemblies also having similarly linear aspects. These latter sub-assemblies are brought together and assembled by insertion into a linear-insert substrate (721), which preferably is a machined copper element providing both the structural back-bone and suitable thermal-sinking element for the resulting linear insert assembly (720) (“LIA”)

In the preferred embodiments, it is preferred that electrical interconnection to the multiple linear insert assemblies of the core-insert assembly (700) is provided by a modular conductor assembly (780), which comprises current conductor, and alternatively any additional sensor connectors for temperature monitoring by thermocouples, RTD's, etc, or pressure monitoring by transducers, or any other appropriate sensor.

It is preferred that extended conductors of the conductor assembly comprise conducting posts (782), preferably comprising copper rod, which is electrically insulated by insertion into a conductor-post insulation-sheath (783) of the conductor assembly, which sheath is a tubular sleeve that preferably comprises a ceramic, and more preferably alumina tube, or alternatively a polymeric compound such as a Teflon-type or polyimide compound. An assembly of the insulation sheath (783) and internal conducting post (782) provides insulated conduction of current between the linear insert assemblies (720) and interconnection interface of the embodied modular receiver tube. A retainer ring (784) of the conductor assembly is a ring-shaped element which incorporates through-holes for positioning outer conductor assembly with respect to the core manifold structure, and is accordingly disposed as a collar-like fitting over the back end of the core manifold structure.

It is preferred that the linear insert assemblies (720) comprise linear assemblies of MJPV die that are connected electrically in series, so that each linear insert assembly (720) is electrically connected to a power load by means of two circuit contacts (719) (753), which are positioned at opposite ends of each respective linear insert assembly. Accordingly, the conductors of the conductor assembly are connected to each of the two circuit contacts at opposite ends of each linear insert assembly by means of an electrical connector. Accordingly, inner conductor array (788) of the conductor assembly comprises its respective insulated conductors (782) (783) that are insertable into the linear through-hole openings (792) and extend up to a connection at the front of the core-insert assembly (700), where front-end connectors (785) comprise electrical connectors interconnecting between the inner array of conductors and the first connector spine element of the linear insert assembly, wherein such connections are preferably soldered, or alternatively provided by standard screws utilized for wire/terminal interconnects.

Conversely, back-end connectors (786) comprise electrical connectors interconnecting between a conductor post of the outer conductor array, the outer conductor array (789) of the conductor assembly, and the adjacent end-piece contactor (753) of the spine-diode assembly, accordingly such contactor residing at the back-end of the associated linear insert assembly, where connection is provided to insulated conductors protruding through the retainer ring (784).

The insulating insert-plug includes inner hole pattern (796) of the insulating plug for guiding and housing the inner conductor array, and outer hole pattern (797) of the insulating plug for guiding and housing the outer conductor array, so that these hole patterns of the insulating insert-plug provide a demountable connection between the conductor posts and connectors of a mating mount receptacle, which are appropriately terminated by mating electrical interconnects.

Accordingly, there are preferably separate circuits provided for each of the linear insert assemblies; rather than connecting all, series-connected, linear MJPV arrays into a single larger circuit, so that, preferably, current from each linear insert assembly can be independently collected and monitored for purposes of diagnostics and for purposes of tracking via monitoring of relative power output from each of the linear insert assemblies.

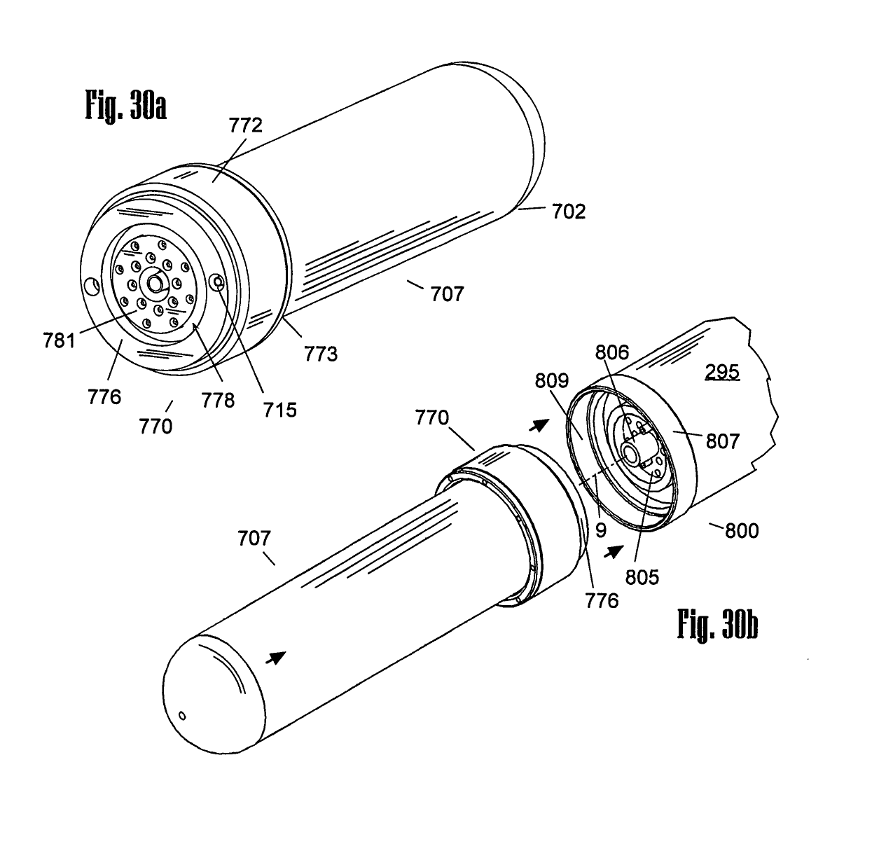

Structural support for the conductor assembly, as well as mounting and insulating means, are provided by an insulating dielectric plug (787) that is formed as a cylindrical insert, preferably of Teflon, or alternatively of other suitable polymer, composite, or ceramic, which is formed with concentric hole-patterns of through-holes, through which the insulated conductors of the conductor assembly are fed. The insulating dielectric plug (787) is subsequently utilized as a central insert comprising the central region of the receiver tube's (707) support base (770). Bottom interfacing surface (781) of insulating plug is accordingly part of the interfacing surface of the receiver tube (707) support base (770) in its interface to the receptacle module (800), in FIG. 30. A central tube passageway (779) in insulator plug (787) of the embodied conductor assembly, coaxial to its central axis (9), provides a passageway for passing through the center-tube (703) and associated quick-disconnect (705) of the SGTA.

In the preferred embodiments, a support core-manifold structure (790) is preferably formed from a single piece of copper alloy, though it may comprise other metallic, semi-metallic, or dielectric materials; for example, it may comprise a sintered aluminum oxide, aluminum nitride, or an aluminum alloy. Preferably though, the insert manifold comprises a material that provides excellent thermal conductivity. The LIA insert modules (720) are preferably mounted onto the core-manifold structure so as to be effectively heat-sinked on each of the three, external, non-PV faces (723) (724). There is accordingly formed radial fin features (791), which are formed into the insert manifold structure, wherein such radial fin structures are linear taper features parallel to the central axis (9) of the manifold structure. Thus, both heat-Sinking bottom surface (795) and heat-sinking side-wall surfaces (794) formed by the manifold core's fin features contact the corresponding taper surface of the linear insert assembly.

Linear through-hole openings (792) are formed in the core-manifold structure for housing the insulated conductor posts (782, 783) of the inner conductor array of the conductor assembly; and, accordingly, the linear through-hole openings are disposed to contain the conductors that extend to and connect electrically to the first spine contactor (719) residing at front end, the forward end, of an adjacent linear insert assembly.

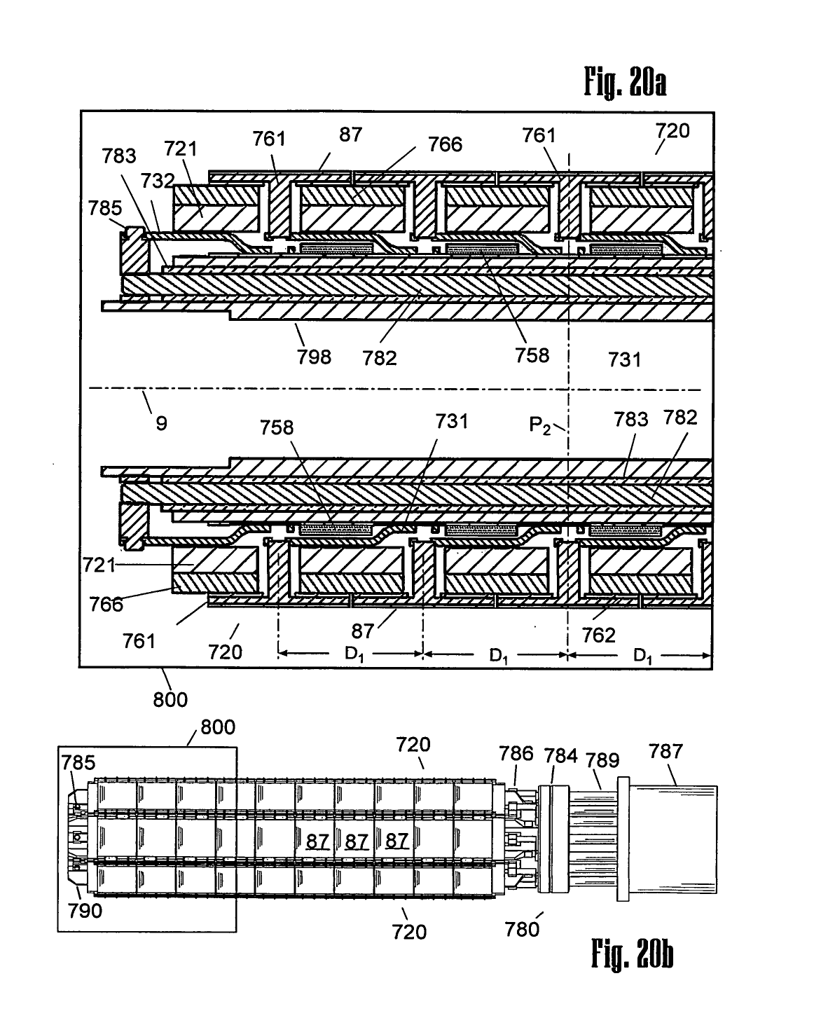

At its back end, the core-manifold structure (790) provides a substantially cylindrical mounting surface for sliding onto of the conductor assembly's retaining ring (784), and so it is preferred that the core-manifold structure (790) have a reduced region (793) at its back end for mating to the retaining ring, where electrical connection between the insert assembly back-end terminal connector (753) and the adjacent conductor of the inner conductor assembly is made, in FIGS. 20-22, via back-end electrical connector (786).

The core center-hole feature (798) of the core-manifold structure (790) is a straight through-hole feature centered upon central axis (9) coincident with central axis of the embodied receiver tube (707), wherein such core center-hole is disposed for bonding to the HTF-carrying center-tube of the glass tube enclosure (702), such bonding preferably comprising a relatively low-temperature commercial solder in range of 200 C melting point.

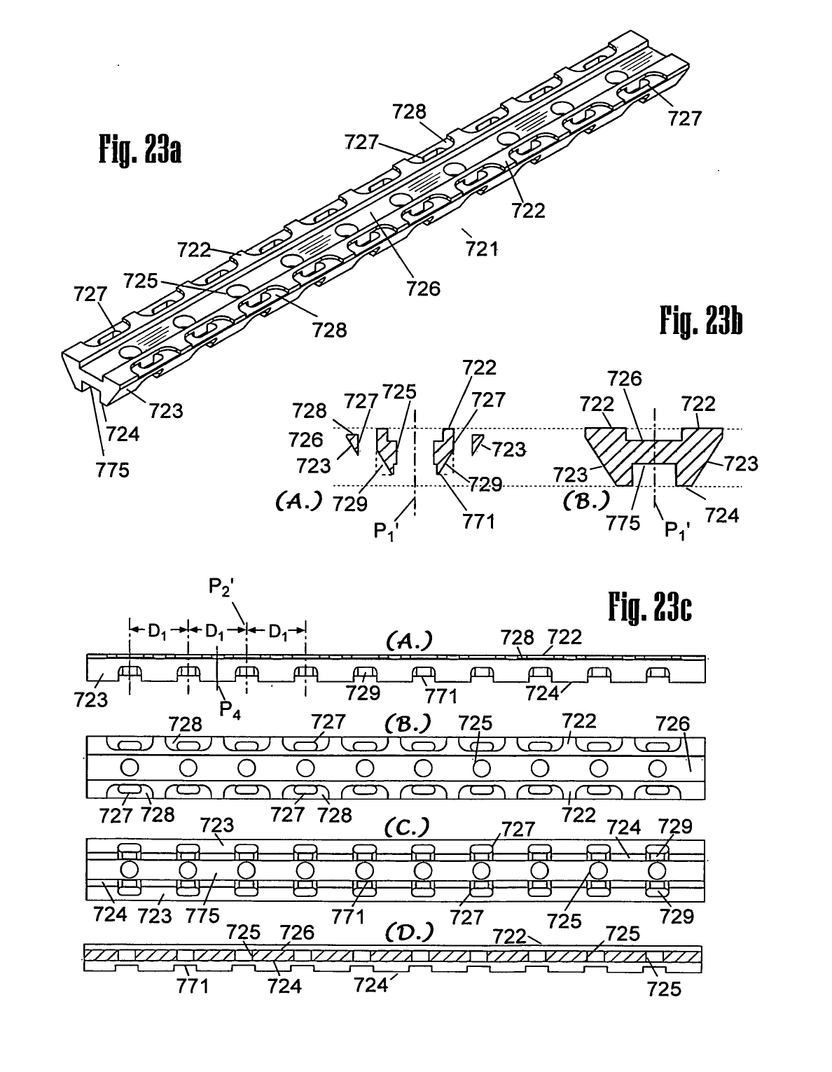

A linear-insert substrate (721) (“LIS”) is accordingly fabricated to provide a substrate of planar aspect roughly equivalent to the attached linear MJPV array of the LIA. The LIS comprises several machined features, including top surface (722) of insert substrate that is subsequently bonded to insert top-plane assembly (760). The LIS further incorporates tapered side-wall surfaces (723) on either side of this insert substrate, the side-wall surfaces extending to a bottom surface (724), so that the end-view aspect of the substrate is roughly trapezoidal, in FIG. 23. Additionally, a linear pattern of center-line openings (725) are drilled vertically through the LIS between its top and bottom surfaces, wherein such through-holes are spaced at spacing interval D₁ equivalent to the pitch of the MJPV dies (87) that are to be attached to the resultant LIA.

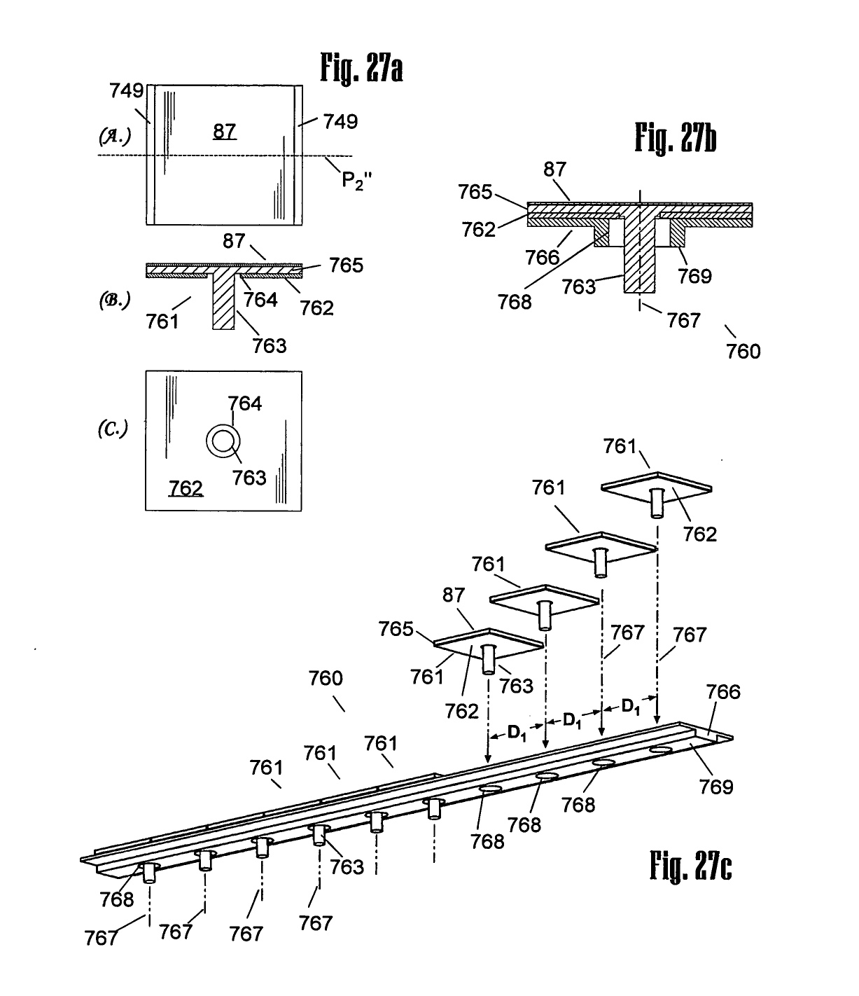

It is additionally preferred that a top channel feature (726) and bottom channel feature (775) are cut into the top surface and bottom surface, respectively, of the LIS. The top surface and walls of the square-profiled top channel feature (726) are disposed so as to provide a mating surface that contacts and is bondable to the bottom-side surface including step-raised reinforcement feature (769) that reinforces the linear-array substrate (766), in FIG. 27, which is preferably bonded to the top surface of the LIS in a subsequent step. In addition to centerline openings (725), additional through-hole features are milled, or otherwise formed, on either side of each centerline through-hole feature; namely, short slots are formed, comprising edge-contact, passageway features (727) of the insert substrate. The edge-contact passageways are formed as oblong openings to accommodate a planar, or substantially oblong, cross-section of conductor that is to be passed through this feature.

A pattern of recessed seating surfaces (728) is also formed into the top side of the US, wherein each edge-contactor passageway feature (727) is effectively modified at its top to provide a recessed flat surface at the vicinity of each edge-contact feature, in FIG. 23. The recessed seating surface is a recessed flat displaced downward from the top surface (722) approximately 1-2 millimeters so that an edge-contact element may be disposed within this recessed space.

It is also preferred that cross-wise cut slots (771), interconnecting and centered on each set of openings associated with an individual MJPV die assembly (761), which set comprises center-line opening (725) and two edge-contact passageway features (727) disposed on either side of the instant center-line opening (725). Accordingly, such plane centrally intersecting these aforementioned features is exemplified by plane P′₂, in FIG. 27c, wherein the pitch, or distance between any two adjacent such planes will accordingly, again, be the pitch of the MJPV array, or D₁, wherein the MJPV die assembly (761) are centered at each of the centerline openings, in FIG. 27c(A.).

In the presently embodied Linear Insert Assembly, with regard to the LIA's electrical conductors that interconnect the individual MJPV arrays (87) of the embodied LIA to the conductor assembly (780) of the embodied receiver tube (707), it is preferred that such LIA conductors be fabricated as modular, pre-assembled assemblies that are preferably manufactured in a continuous strip, or chain-like strap, that is subsequently cut into standardized lengths appropriate for the particular manufactured receiver tube (707).

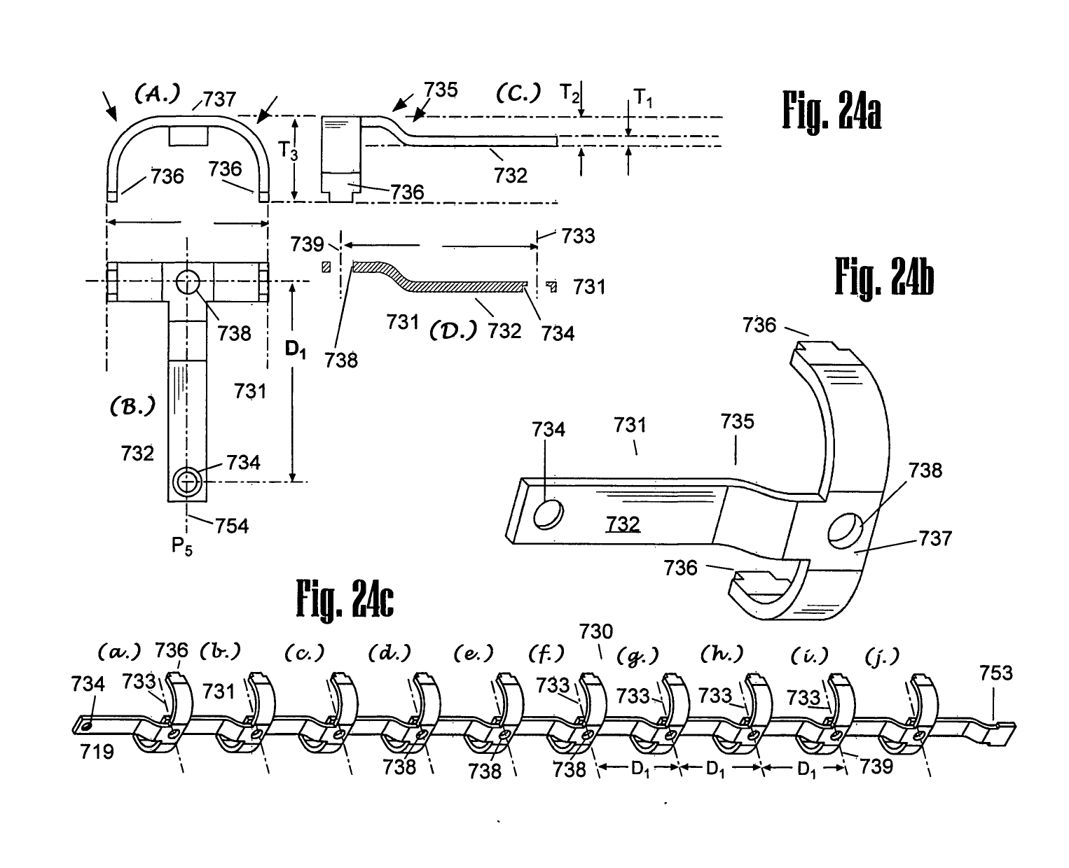

Referring to the continuously manufactured chain-like sub-assemblies of the embodied LIA, and specifically, continuous chain-like assemblies of electrical conductors, a primary sub-assembly of the LIA fits into the back-side trench feature (775) and contiguous features of the LIS, forming a central “spine-like” linkage of central conductors for electrically contacting the back side of each MJPV die in the resultant LIA. Accordingly, this “spine assembly” incorporates a plurality of daisy-chained metallic contacts of an iterated unit with pitch spacing D₁ roughly equivalent to the resultant pitch of the close-packed MJPV die incorporated into the resulting LIA. One such central conductor, or spine element (731) is a “T”-shaped metal article accordingly having a central elongate member intersecting the center of a lateral cross-bar member, in FIG. 24. In addition to having a “T”-shaped aspect, the lateral feature of the “T” extending from either side of the spine element's central member (732), such lateral feature (736) is preferably bent to form a “U”-shape in a separate aspect, as viewed down the planar length of the central member (732). The spine element is preferably fabricated by punching from a metal strip, which is preferably copper of strip thickness preferably of 0.002-0.020 inches, and width of 0.05-0.2 inches, though this is ultimately dependent upon the MJPV dimensions chosen. Two through-hole features are formed along the central member (732) of each pine element. A first hole feature, central opening (738) having central axis (739), is centered upon the central flat region (737) of the spine element at the intersection of centerlines of the lateral member (736) and vertical/central member (732). The second hole, post-contact opening (734), having central axis (733) of the post-contact opening, is formed at the distance D₁ from the central opening (738), located along the centerline of the central member (732) roughly at its end region, in FIG. 24. In daisy-chained assemblies of the spine contactor elements (731), a spine assembly (730) of spine elements will be substantially aligned along the centerline axis (754) of the spine element's vertical members, such that the central axis of a first spine element's central opening (738) will be coincident with the post-contact central axis (733) of an adjacent spine element, wherein this linkage is repeated, in FIG. 24c.

The lateral members of the embodied spine element (731) are each utilized for contact to the top-side contact region of the embodied MJPV die, each lateral member comprising an edge-contactor (736) of the spine element, such that it is terminated so as to provide extension to the vicinity of such top-side contact regions of the MJPV array/die, which is attached immediately above the instant spine element.

The edge-contact features (736) on either side of the spine element (731) are of appropriate dimension to allow press-fit into the oblong passageway features (727) disposed on either side of each centerline opening (725) of the LIS, where the mating of these respective features requires clearance for insulated passage of the U-shaped contactor legs of the spine element (731). Accordingly, chamfered inner surface (729) of the insert substrate is a clearance-creating chamfer of the edge formed between the bottom of oblong passageways (727) and cross-wise cut slots (771), in FIG. 23b (A.), where dashed lines indicate the sectional profile before chamfering to the specified chamfer surface (729).

The embodied spine-diode assembly (750) accordingly incorporates the combined assembly of the spine assembly of daisy-chained spine elements and diode tape assembly. The diodes are accordingly positioned between upper-plane (751) of the aligned spine elements and lower plane (752) of the aligned spine elements, and further, each diode is positioned along the linear direction of the spine-diode assembly so as to reside within the clearance space formed by displacement bend (735) in spine central member (732), whereby space is formed between planes defined by spine element surfaces (732) (737), as defined by distance T₂.

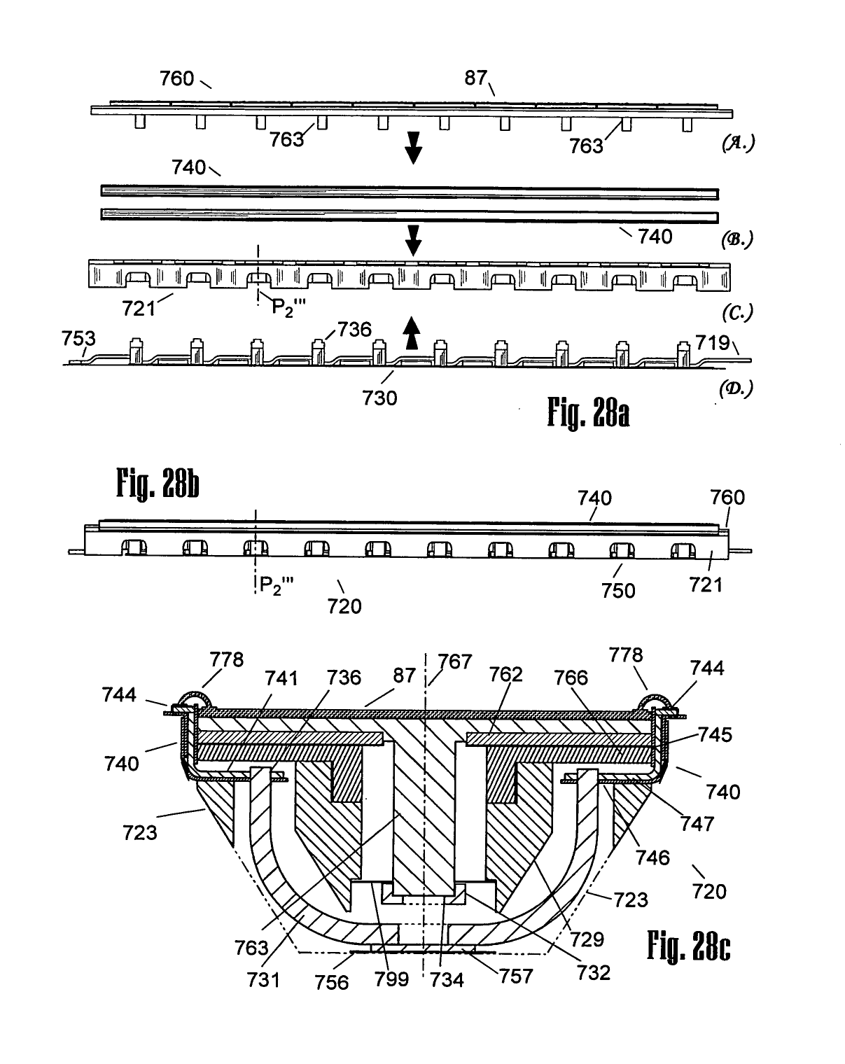

The continuously formed spine assembly is formed into relatively short chains of several elements corresponding to the number of MJPV die per LIA (720) in the desired receiver tube. Each resultant chain of spine elements is accordingly terminated by a back-end-piece contactor (753), which comprises the central leg portion (732)(735)(737)(738) of the last spine element of the instant chain, and first spine contactor (719), with its post-contact opening (734), comprises front connection (719) for connection to front connector (785) in the instant spine assembly (730), in FIG. 24 and FIG. 28. At the back end of the LIA, the end-piece contactor (753) is formed by shearing off the two edge-contactors (736) of the U-shaped aspect, in FIG. 24a-b.

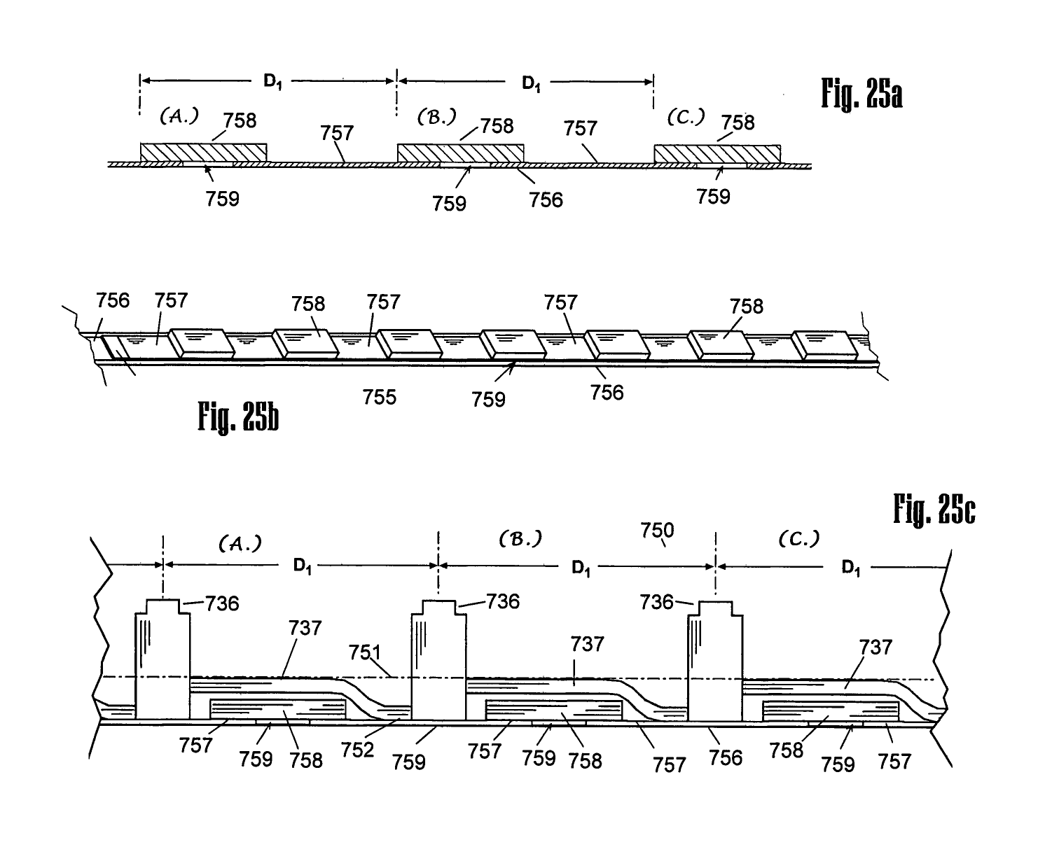

It is preferred that the spine assembly (730) is incorporated as a subassembly into a more complex continuous, tape like assembly—namely, a spine-diode assembly—that also incorporates diodes for reverse-current protection. Accordingly, a diode-tape sub-assembly (755) is also incorporated into the embodied spine-diode sub-assembly. The diode-tape sub-assembly is preferably a pre-made continuous tape that incorporates a polyimide (e.g., Kapton) tape as a structural and insulating layer, over which is formed an intermittent copper layer that is interconnected by an integral series of diodes that are electrically bonded, preferably soldered to the copper layer, in FIG. 25.

The diode-tape copper layer (757) of the diode-tape assembly preferably comprises electrodeposited copper metal layer deposited onto the insulating diode tape (756). The diode-tape copper layer is digitized to comprise a spatially regular series of electrically isolated copper trace-regions, with pitch of such isolated regions roughly equal to the pitch of the MJPV array, D₁, which is spacing between adjacent MJPV die/arrays.

The diode (758) of the diode-tape assembly is preferably that suitable for reverse-current protection in the series-connected PV arrays, and typically comprises a PCB mount package having coplanar contact surfaces. Opposite electrical contacts of one such diode are accordingly soldered to each of two adjacent copper trace-regions along the diode tape, so that each diode effectively interconnects, electrically, adjacent regions of the diode tape layer in the conventional manner, wherein the diode accordingly is disposed over the non-metallized region (759) that otherwise electrically isolates the two instant copper regions of the diode-tape assembly.

While it will be appreciated that the embodied spine element can be extended so as to allow direct wire bonding from it to contact surface of an adjacent MJPV die, it is preferred that an additional metallic contact element (741) be incorporated for purpose of more practical assembly, and for providing an extension particularly suited for bonding to the MJPV module used. This contact element thus provides electrical continuity and extension between a particular spine element and corresponding adjacent MJPV die that is positioned over the spine element and is typically providing a wire-bondable surface.

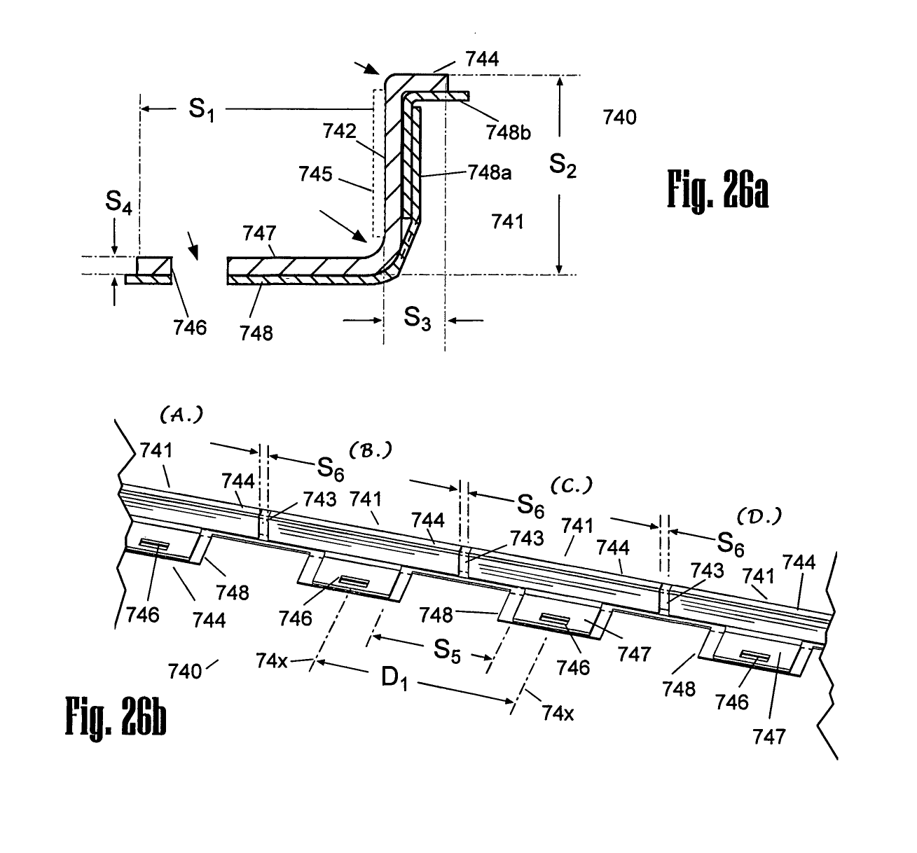

It is preferred that such contact elements (741) be, similarly to the spine-diode assembly, manufactured as a continuous tape or linkage of such elements, which allows for ease of handling, alignment, and installation. This continuous tape of contact elements preferably incorporates necessary insulating layers which separate the contact elements electrically from each other and the adjacent components of the LIA, as well as providing a continuous substrate for manufacturing a continuous tape of such regularly spaced side-contact elements (741), namely as a side-tape assembly (740), in FIG. 26.

The side-tape contact element (741) of the side-tape assembly preferably is formed from a continuous copper strip that is processed through appropriate conversion equipment for laminating the copper tape with insulating cover layers, preferably polyimide/silicone adhesive tape (748). It is preferred that such conversion processes also deform the resultant insulator/copper composite tape into basically a z-shaped cross-section, wherein this cross-section includes an upper segment presenting top wire-contact surface (744), as well as preferably a lower segment comprising lower lateral portion (747) that is substantially parallel to the upper segment. In accordance with the embodied z-shaped cross-section, in FIG. 26, the upper segment and lower segment of the contact element are separated by an intermediate segment, the intermediate segment of the contact element comprising a roughly vertical (in cross-section) side-wall (742), of the side-tape assembly. The accordingly folded copper strip/insulator multilayer composite is subsequently chemically etched to remove intermittent sections of the copper strip, so that the resultant contact elements are thereby separated by intermittent sections of removed material, or via's (743), thereby forming a continuous tape-like assembly of electrically isolated copper contact elements (741).

It is preferred that the contact elements be formed by means of etching, or alternatively, otherwise separating by laser cutting, shearing, or other method, the bent copper tape into a multitude of the contact elements. Chemical etching is preferred since it a proven means to form the described features of the contact elements whilst the contact elements, the remaining z-shaped copper tape, remain attached to the adhesive polymeric tape. Accordingly, wet chemical etching is utilized in the standard way to form an etched via structure (743) of the side-tape assembly. Such etched via structures are formed at a regular interval along the bent copper tape so as to provide the contact elements, which are spaced apart at the preferred PV-die pitch, D₁, of the linear insert assembly.

The contact elements each incorporate a top wire-contact surface (744), so that the side-tape assembly thereby incorporates a piece-wise continuous line of these wire-contact surfaces in roughly a single plane, so as to be readily aligned and incorporated into either edge of the resultant insert assembly. Also embodied and preferably incorporated is continuous front-side tape (745) covering the side-tape sidewall region (742) of the side-tape assembly so as to provide electrical insulation between the contact elements and corresponding adjacent edge portion of the linear insert assembly; namely, the adjacent edges of the according MJPV die and its supporting substrate pad sub-assembly. Each contact element has formed therein, preferably an insertion-hole structure (746), which is formed into the lower lateral portion (747) of the side-tape contact element. Such lower later portion (747) and insertion-hole structure are formed so as to insert into and register against the recessed seating surfaces (728) of the previously embodied LIS, such that the insertion-hole structure (746) is centered over the underlying oblong passageway (727), thereby positioned for mating to the edge-contactor (736) of an underlying spine element (731).

It is preferred that the integration of multiple MJPV die into the disclosed linear insert assembly (720) is enabled by means of a sub-assembly forming the close-packed linear array of MJPV die, namely, an insert top-plane assembly (760) (or ITPA) provides means for combining the close-packed MJPV die-arrays independently of attachment to the LIS, so that various packaging operations can take place prior to bonding of the ITPA to the tope surface (722) of the LIS. The ITPA comprises one linear array of MJPV die in the embodied polygonal PV assembly, which, as embodied in the subsequently formed LIA, comprises ten MJPV die assemblies (761) in the present embodiment.

Prior to assembly of the ITPA, it is preferred that a multitude of mounted-die assemblies (761) be first assembled. The individual MJPV die/array (87) is bonded to a PV-mount substrate (765) that is thereby sandwiched between the MJPV array (87) and an underlying insulating pad (762) so as to form a resultant mounted-die assembly (761). The PV-mount substrate (765) is fabricated so as to incorporate a center-post contactor (763), which is a post-like feature of the PV-mount substrate (765) protruding from the center of the PV-mount substrate's back side. The central opening (764) of insulating layer provides opening for the center-post.

The center-post contactor (763) preferably comprises the same material as the planar portion of the PV-mount substrate, preferably being a copper alloy. The insulating layer (762) is preferably a separately formed alumina ceramic, though it can alternately be any other suitable dielectric material. It is also contemplated that the insulating pad be a thick or thin film coating formed on the back side of the PV-mount substrate, in FIG. 27.

After fabricating of the MJPV die-assemblies (761), it is preferred that these individual assemblies be mounted upon an intermediate linear-array substrate (766). The linear-array substrate (766) of the insert top-plane assembly is preferably machined, or alternatively extruded metal channel, and made from copper or other high-thermal conductivity material.

The central axis (767) of each mounted-die assembly (761) to be integrated onto the ITPA is aligned to a central axis of a centerline opening (768) in the illustrated manner. A series of centerline openings (768) is formed into the linear-array substrate so that each centerline opening provides an opening for pass-through of the current-carrying center-post (763) of the corresponding mounted-die assembly (761) centered over that centerline opening. The central axis (767) of each mounted-die assembly (761) to be integrated onto the ITPA is aligned to a central axis of a centerline opening (768) in the illustrated manner.

As previously embodied, the receiver tube is utilized for concentrator/receiver combinations that can provide a wide range of concentration ratios and concentrator sizes; accordingly, such continuous sub-assemblies as the spine-diode tape and side-tape assembly are appropriately flexible and can be cut at lengths suited for LIA's (720) incorporating any number of the individual MJPV arrays/die (87). In some cases, the MJPV can be manufactured as a rectangular die, so that only one die is utilized for each LIA. In other cases, there can be many smaller die utilized in a single linear array that is connected in series for a higher resultant voltage output and relatively low current output. In the first preferred embodiment disclosed herein, an exemplary LIA incorporates close-packed MJPV die in a row of ten (10) die, where eight of the LIA modules are incorporated into the exemplary receiver tube's polygonal core-assembly (700), which is in this case an octagonal assembly incorporating eight such LIA, though the number of LIA's would typically be in accordance with particular receiver tube size and MJPV die used in a particular circumstance. It will therefore be appreciated that virtually any number of MJPV die may be incorporated by means of the approach pointed out herein.

Accordingly, the embodied tape-like sub-assemblies may be readily adapted to such alternate embodiments. In accordance with the preferred embodiment of an LIA utilizing a row of ten serially connected, commercial MJPV die, The various components of the described LIA are fabricated for accommodating ten MJPV die/arrays. Accordingly, the LIS, spine-diode tape, side-tape assembly, and insert top-plane assembly, are each constructed in accordance with a pitch, D₁, that is approximately equivalent to the relevant dimension of the MJPV die used, which is roughly 1 centimeter (e.g., Spectrolab, or Emcore), and are each made, in the present exemplary embodiment, to accommodate ten MJPV die/arrays, in FIG. 28.

Having fabricated each of the required subcomponents and sub-assemblies, it is preferred that assembly of the LIA is executed by first press-fitting the spine-diode tape assembly (730) into the back of the LIS (721), so that the edge-contactor elements disposed on either side of the spine-diode assembly are fitted into the oblong passageways of the LIS, and so that the remaining portions of the spine-diode assembly are placed into the space formed by the bottom channel feature (775) of the US. Such insertion of the spine-diode assembly into the LIS will result in edge-contact features (736) of the spine elements protruding above the plane of the recessed seating surface (728), where each edge-contact feature can be made to snap into the insertion hole-structure (746) of the side-tape contact element (741). Engaging spine edge-contact feature to contact element's insertion hole is executed by means of lowering respective lower-lateral-portion (747) of each contact element so that the underlying insulating layer (748) comes into contact with the recessed seating surface (728), in FIG. 28. The mechanical and electrical connection between each spine element's edge-contact feature (736) and the adjacent contact element (741) is then strengthened by soldering the mated pair together at the region of insertion into the insertion hole-structure (746). It is also preferred that this region around the edge-contactor and within the recessed seating surface (728) be encapsulated with a silicone resin, which is not shown for purposes of clarity.

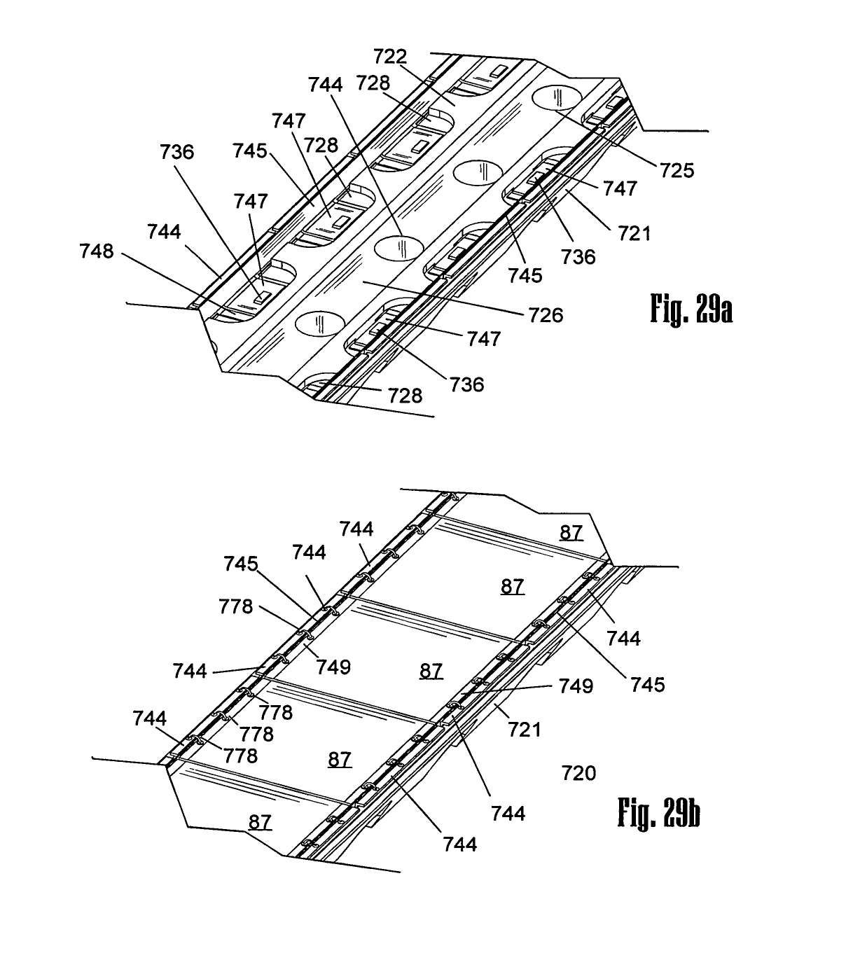

After installation, soldering, and potting of the side-tape and spine-diode assemblies, it is preferred that the ITPA (760) be subsequently bonded to the top surface (722) and top channel feature (726) of the LIS. This is preferably performed using a relatively low-temperature solder, such as in the range of 180 C-200 Celsius, whereas the previous spine and side-tape assemblies were preferably soldered together with a relatively higher-temperature solder, in range of 220 Celsius. Solder bond connections of the ITPA are preferably also performed at the interface between post feature (763) of the top-plane assembly and the post-contact feature (734) of each spine element. After all such required sub-assemblies of the LIA are assemble, it is preferred that wire-bonding is then performed as a subsequent step, by wire-bonding of the MJPV top contact surface (749) to the top wire-contact surface (744) of each corresponding adjacent contact element, in FIG. 28-29, wherein preferably multiple wire-bonds are made to each side of each MJPV die/array.

On the opposite side of the spine-diode assembly from the insulating diode tape (756) there is preferably also disposed an upper insulating tape (799) that effectively provides electrical insulation that electrically isolates the lateral bottom-channel surface (775) of the LIS from central member (732) of an adjacent spine element (731). It is preferred that such insulating tapes (799) (756) (745) that provide electrical isolation between opposing surfaces disposed on either side of such tapes; such tapes are additionally functional in allowing relatively high heat transfer between such opposing surfaces, due to their relatively thin cross-section, which is typically a thickness less than 200 micrometers.

The mating of edge-contactor portions (736) of the spine elements (731) to the edge-contact elements (741), which takes place in recessed seating surface (728) of the LIS modules (721), is preferably conducted prior to mounting of the insert top-plane assembly ITPA (760), so that higher access and visibility allow for low-cost manufacturing of the LIA, in FIG. 29a.

It is embodied that a plurality of wire-bond interconnects (778) are utilized to interconnect the MJPV die contact surfaces (749) to adjacent wire-contact surfaces (744) of the flanking side tape assembly's (740), in FIG. 29b. As previously embodied, it is preferred that the side-tape contact element (741) be separated from the adjacent die assembly (761) by a thin organic layer. It is preferred that this layer, the front tape layer (745) possess adhesive surfaces on both of its sides so as to maintain good thermal contact and mechanical fastening between the contact element and the die assembly (761).

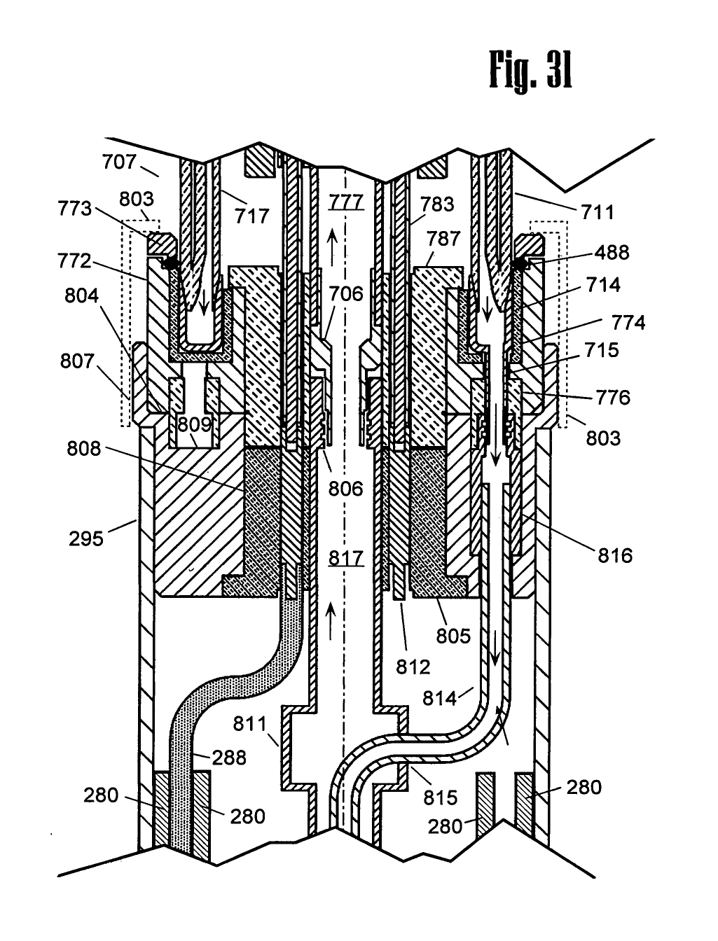

The embodied tube base-support assembly (770) comprises a support base of the inventive modular receiver tube, wherein the base provides an interconnection means between the core-insert assembly (700) with attached conductor assembly (780), and a receptacle of the underlying solar tracker, in FIGS. 30-31.

A base housing (772) is preferably constructed of a metal alloy, most preferably an aluminum alloy, of alternatively, stainless steel or other suitable material; alternatively, it is constructed of PTFE or other polymer.

The Insulator plug (787) of the conductor assembly is also a central portion of the base-support assembly (770), wherein the insulator plug is disposed, with gasket sealed perimeter, within central opening (713) of the annular base support housing (772). Central tube passageway (779) in insulator plug of the embodied conductor assembly, coaxial to its central axis (9), provides a passageway for passing through the center-tube (703) and associated quick-disconnect (705) of the SGTA.

Various mechanical means of the prior art may be used to mechanically secure the SGTA (702) to the support base assembly (770), as well as to secure the resultant modular receiver tube (707) to the receptacle. Such mechanical securing mechanisms can include clasps, clamps, semi-permanent bonds, or a twist-lock mechanism wherein keyed features are utilized appropriate to uniquely positioning, inserting, and twisting to lock into place, as is well-understood in the prior art of male-female couplings.

In the preferred embodiment, a retainer ring (773) is a ring-shaped compression ring providing compression of the sealing gasket (or o-ring) disposed underneath the retainer ring for purpose of mechanical support of the SGTA and sealing the base-support assembly from the environment. The inner metallic tube (703) of the SGTA is bonded to the interior surface (798) of the core-manifold, by means of a reflow solder, preferably with melting point below that of solders used in the attached core-insert assembly (700). In this way, core insert assembly (700) and SGTA are separated and replaced, which is by means of the bonding or de-bonding of the central tube to the core-manifold central interior surface (798).

Within the base-support assembly (770), an insulating polyimide liner (774) is disposed as an annular U-shaped liner disposed between metallic trough (714) and support base housing (772). Since the return fluid may be at temperatures exceeding 250 Celsius under some conditions, the metal trough walls preferably also comprise vacuum-insulated, spaced-double-wall, layers.

The annular keyed structure (776) is preferably composed of a Teflon-type material, or alternatively a suitable ceramic such as alumina, depending on ultimate temperatures that are desired. The annular keyed structure provides a mechanical guiding structure for accurately guiding the mating action between the HTF return-flow connectors (715) (816) in coupling of receiver tube (707) to mounting-receptacle assembly (800), wherein the receptacle-side HTF-return connector (816) is preferably insulated by a polyimide liner (818). Upon mating the modular receiver tube (707) to mounting-receptacle assembly (800), passageway space (777) formed for supply fluid by structure of center-tube (703) is thus made contiguous with receptacle flow space (817) of the underlying tracker, in FIG. 31.

The receptacle-housing structure (807) is preferably formed from a metal, or alternatively high-temperature polymeric material or composite. The receptacle housing structure incorporates central interior surfaces forming central opening (808) of receptacle housing provides housing for the receptacle assembly (800). An annular recess (809) of receptacle mates with corresponding annular keyed ring (776) of the modular receiver tube.

A receptacle insulator plug (805), preferably composed of a ceramic, or alternatively, such high-temperature polymers as PTFE (Teflon), PEEK, or polyimide, is disposed centrally within the receptacle module so as to provide demountable electronic interface to the embodied receiver tube's insulating plug (787) and to house inter-connectors (812) between corresponding electrical interconnects of the embodied receiver tube's support base and conductor lines (288) of the underlying tracker, wherein the multiple described electrical connections to the receiver tube are thereby provided. The HTF supply interconnect (705), brazed to SGTA center tube (703) by means of brazed seal (708), of the demountable receiver tube, connects to stainless steel female quick-disconnect (806) of the receptacle module (800) via mechanically loaded o-rings of the disconnect (806) in accordance with higher-temperature quick-disconnect designs. Similar to the metal trough (714), such connectors may also comprise double-walled, vacuum-insulated structures in certain alternative preferred embodiments. Fluid disconnects (816) (806) of the receptacle are preferably o-ring sealed disconnects, utilizing high-temperature polymers, preferably silicone, or alternatively Kalrez, or other polymeric/inorganic composites utilized in high temperature seals.

It is preferred that the receiver tube module be utilized in conjunction with a receptacle that provides demountable interconnection for each of the described fluid and electrical circuits. Accordingly, receptacle assembly (800) is insertable into the nipple tube (295) and adapts the HTF and electrical connections of the previously embodied tracker for demountable interface with the presently embodied receiver tube (707). Clamps (803) are preferably incorporated into the receptacle/nipple structure for securely clamping the receiver module, in FIG. 31. The receptacle module is preferably formed so as to be attachable to the tubular nipple structure that protrudes upwards from the embodied solar collectors center. The receptacle module incorporates a registration bottom surface (804) of receptacle against which the support base housing structure (772) is mechanically contacted in mounted position.

It is preferred that the sealed glass tube assembly have one return flow orifice (715) for HTF exiting the sealed glass tube assembly. Depending on desired output temperature and geographic location, as well as other factors effecting desired flow rate, the sealed-glass tube assembly can be readily constructed with wider clearances in annular flow spaces, and more than one trough fluid connector (715). With one or higher number of these return fluid connectors incorporated into the preferred metal trough of the sealed-glass tube assembly, it is preferred that the support base of the receiver tube (770) include a concentric annular keyed structure (776) extending from the underside of its base housing for protecting and housing such return-side fluid connectors. Such annular keyed structure is “keyed” in the sense that it fits into the annular recess (809) of the receptacle module (800)

An HTF, return-line, feed-through section (811) of central tube allows for the vacuum-insulated return tube (814) to be further encapsulated by the supply side fluid as a coaxial assembly that is thereby appropriately configured for interface with rotating unions that incorporate coaxial feedthrough of supply and return fluids, such as embodied in the embodied tracker herein.

The insulated fluid return tube (814) is preferably a vacuum insulated double-walled tubing of an stainless-steel type composition, preferably one that is commercially available, such as provided by Insulon, or, alternatively the vacuum insulated tubing of the present invention may be custom made utilizing known and published methods for providing vacuum insulated tubing. Accordingly, feed-through (815) of insulated line to central conduit is preferably formed as a welded assembly.

It is also embodied that reflective means are incorporated into the inventive receiver module for redirecting incident radiation arriving from the solar collector, wherein, in particular, a polygonal end-mirror (480) is disposed at either end of the core-insert assembly (700) and positioned adjacent the first and last MJPV die modules of each linear insert assembly, so that an end-mirror is provided at either end of the core-insert assembly (700), and slides over the attached circular array of LIA (720). A circularly symmetric array of facets (481) are accordingly formed, by stamping, into a single ring of reflectively coated metal foil/strip so as to form the polygonal end-mirror. An inner edge (482) of polygonal end-mirror is accordingly polygonal in its aspect, as viewed along the circular end-mirror's central axis (484). An outer edge (483) of polygonal end-mirror is accordingly circular in its aspect, as viewed along the circular array's central axis (484).

The central axis (484) of the polygonal mirror is thus coincident with the central axis (9) of the receiver tube, so that in the case that there is light propagating through the tube that would otherwise be incident upon the core assembly in a surface region displaced from the MJPV absorber, such light is reflected by the polygonal end-mirror so as to be incident upon the MJPV absorber. Preferably the polygonal end-mirror is a multi-faceted single ring of relatively thick metal foil, typically 100-250 micrometers thick; alternatively, the end-mirror comprises a conical frustum having similar inner and outer diameters so as to be similarly positioned.

In accordance with earlier-filed patent disclosures by same applicant, the core assembly can also be incorporated into a concentric assembly of straight-walled transparent tubes, preferably comprising silica glass. It is preferred in this alternative embodiment, that a polymeric trough insert (485) forms an annular collection space (486) into which return HTF flows from the annular flow space (211) of the glass enclosure. A compressively sealed o-rings (488) are disposed so as to seal the polymeric trough insert (485), wherein annular collection space (486) provides a return passageway conveying fluid from the annular passageway. As in previous patent application by same applicant, an end-cap (224) is utilized.

Returning now to construction of the concentration optic used for irradiation of the receiver module, certain alternate preferred embodiments are disclosed herein. The multi-frustum solar concentration optic disclosed in earlier embodiments may utilize any of a number of internal cores within the interior of each frustum structure (80). In an alternative preferred embodiment of one such internal frustum-core structure, general principals and structural embodiments are retained, with improvements and advantages comprising more economical production particularly under conditions of lower production and smaller concentrator sizes. In a presently embodied alternate frustum core structure, vertical and lateral structural elements, introduced in earlier preferred embodiments, are once again embodied with different internal core structures and methods. In accordance with previous embodiments of core structures in earlier patent filings by same author, an alternative core structure comprising a series of vertical and horizontal elements is preferably formed from aluminum-based foils.

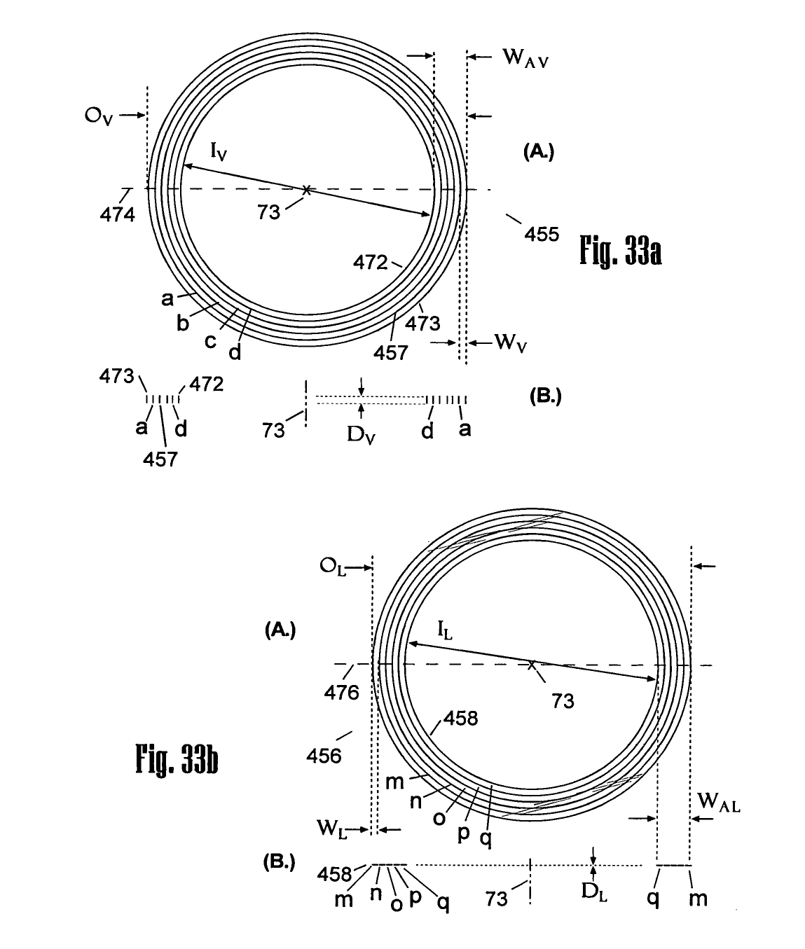

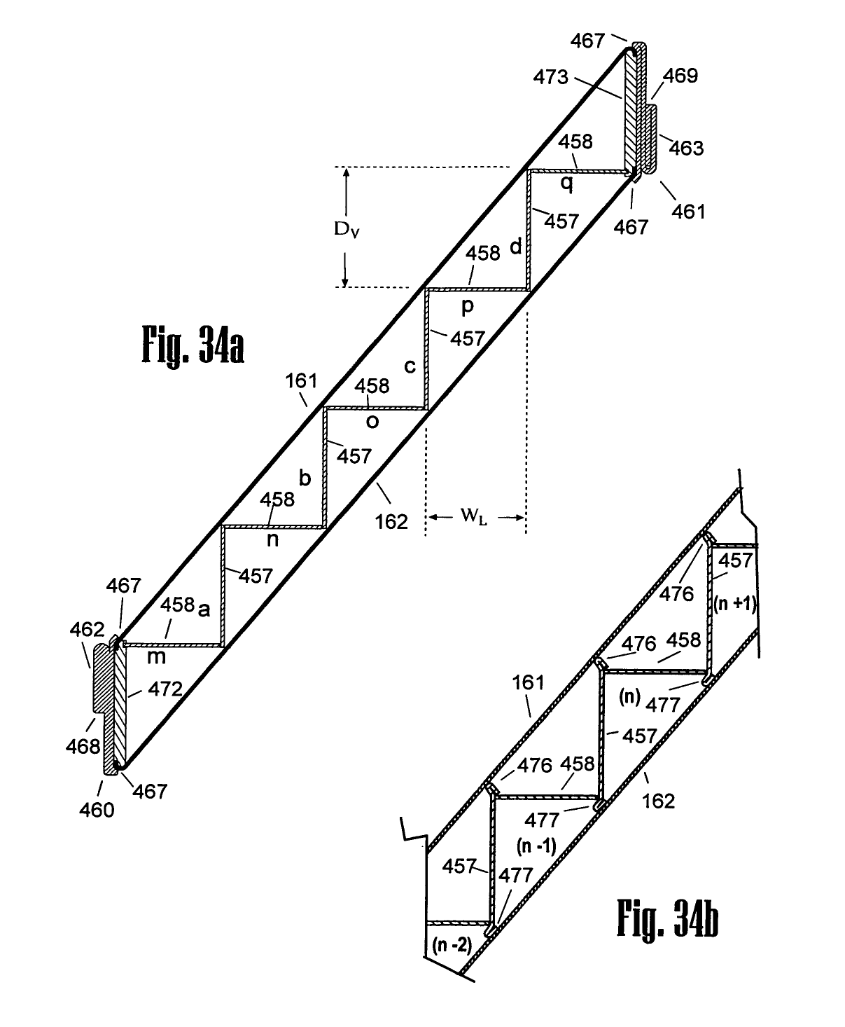

Specifically, in FIGS. 33-34, two sets of ring-shaped elements are fabricated from aluminum-based metal foils. The first set of ring-shaped elements, in FIG. 33a, vertical array (455) comprises a concentric assembly of cylindrical rings, a, b, c, d, that provide vertical structural elements of the presently embodied frustum-core structure, so that such ring-shaped elements have a sectional profile, a through d, in FIG. 33a, that is parallel to frustums central axis (73). The cylindrical rings (457) are formed as continuous rings, and are preferably formed from a continuous rolled strip, which is cut in predetermined lengths so that the ends can then be resistively welded together, or joined by other alternative fastening means.

A second array of ring-shaped elements, lateral array (456) of lateral rings, m, n, o, p, q, in FIG. 33b, are preferably slit, with accordingly circular path, from a single sheet, such that the interior diameter of a particular lateral ring in the array, “m”, is equivalent to the outer diameter of an adjacent ring—specifically the next adjacent smaller ring “n” in the array—such that these two diameters are substantially equivalent, in accordance with the preferred method of forming both such edges of these adjacent rings by a single cut into a single sheet. Accordingly, the lateral rings of the array are preferably those resulting from making single circular cuts into a sheet of aluminum (or alternatively, stainless steel) foil so that each adjacent lateral ring produced from the sheet is separated from its adjacent lateral ring by means of making a circular cut that simultaneously forms two edges of the resultant core structure. The individual lateral rings (458) of the lateral array thus comprise concentric rings that are preferably cut from a single sheet of aluminum foil, wherein aluminum foils of the presently embodied frustum core are preferably in the range of 20 to 200 micrometers, though foils outside of this range are readily utilized.

The previously embodied vertical array (455) and lateral array (456) are combined to form the internal core of a single frustum section, such as is embodied using various core media, as disclosed previously in the present invention, or in previous related patent applications. Accordingly, the frustum structure (80) has an inwardly facing reflective layer (161) having a substantially unique angle with respect to the central axis (73) of the frustum, as measured in a major sectional plane containing the central axis.

Similar to previous embodiments, the embodied frustum structure (80) incorporate mechanical registration surfaces and load-bearing surfaces at vicinity of the inner diameter and of the outer diameter of the frustum structure's (80) reflective surface. In the present invention, such terminating edge-surfaces of the frustum are preferably incorporated as compound structures incorporating closely fitted, concentric, ring-shaped, structural elements, wherein the reflective front surface-layer (161) and back-side cover-layer (162) are preferably deformed at their inner and outer substantially circular, edges so as to be trapped between opposing surfaces of a compound edge-assembly structure, namely, inner compound edge-structure (460) and outer compound edge-structure (461).

Accordingly, the presently embodied frustum structure preferably incorporates a compound edge-surface assembly at vicinity of each of its innermost diameter and at its outermost diameter. At the inner diameter of the frustum structure (80), the inner frustum-core interface structure (472) of the inventive frustum structure is disposed in interlocking relationship with lower interlocking ring (460). At the outer diameter of the frustum structure (80), the outer frustum-core interface structure (473) is disposed in interlocking relationship with upper interlocking ring (461). These interlocking elements provide trapping regions (467) wherein opposing surfaces of the interlocking elements effectively trap an edge region of the frustum cover layers (160) (161). The deformation region at each respective edge of the front and back layers is effectively retained by trapping between surfaces of the respective compound edge assemblies.

It is also an alternative embodiment that the inner and outer frustum-core interface structures (472) (473) incorporate an extended lip structure (471) supporting relatively wide edge region of cover layers (160) (161), in FIG. 34a. Preferably the embodied structural components comprise aluminum alloys, which are bonded together in previously embodied fashion by organic-resin adhesives. It is also preferred that lower interlocking ring (460) incorporates the load-bearing features and registration surfaces for the outer edge-surface region of the frustum, whereas, upper interlocking ring (461) incorporates the load-bearing features and registration surfaces for the outer edge-surface region of the frustum.

A deformation region (467) of frustum surface layer comprises a deformed edge region, preferably formed as bent intermittent tab formed into inner and outer edge, comprising annular edge-region of the surface layers (161) (162) that is preferably up to 0.5 centimeters from the layer's edge, and more preferably within less than 0.3 centimeters from edge, in FIG. 34a. The surface is deformed so as to be bent, preferably by a stamping operation, toward the core-side of the surface layer. from extruded

As with earlier embodiments of the individual, stack-able frustum structures, termination surfaces formed into inner and outer edges of the embodied frustum structure provide both mechanical bearing surfaces as well as alignment surfaces for communication of mechanical forces between adjacently stacked frustum structures. Accordingly, in the present embodiment, over-hanging interlocking feature (462) is formed into the frustum structure's inner edge-surface, whereas under-hanging interlocking feature (463) is formed into the frustum structures outer edge-surface.

The over-hanging interlocking feature (462) is formed with inner registration surface (468) disposed at frustum structures inner edge-surface. The under-hanging interlocking feature (463) is formed with outer registration surface (469) disposed at frustum structures outer edge-surface. Therefore, in mating two frustum structures together, the overhanging feature of the upper frustum structure will come to rest upon the under-hanging feature of the lower frustum structure, with the registration surfaces of the respective frustums defining precisely their relative position along the central axis (73), and their position relative to each other, in FIG. 34b.

In FIG. 34b, an alternative preferred embodiment is embodied wherein each cylindrical core ring (457) is terminated at its upper and lower edge by a folded bead formed by upper seamed edge (476) and lower seamed edge (477), which accordingly is disposed at the cylindrical ring's interface with the lateral rings (458), in the vicinity of the frustum inner layer (161) or frustum outer layer (162). In the present embodiment, it is preferred that the edges of the core ring (457) be folded at roughly 180 degrees in a first fold, thereby forming a folded seam as commonly provided in sheet metal processing art. It is additionally preferred that at least a second bend, or crease, is formed just inside the seam, so that a mechanical registration edge is formed for registration of the lateral ring at a unique elevation along the seamed cylindrical ring. It is additionally preferred that the seam feature (477) (476) on both upper and lower edge of the cylindrical ring (457) be deformed toward the constructed frustum center

Reference throughout this specification to “in a preferred embodiment” or “an embodiment” means that a particular feature, structure, process, or characteristic described in connection with the embodiment is included in at least one embodiment of the present invention. Thus, the appearances of the phrases “in a further embodiment” or “in a preferred embodiment” in various places throughout this specification are not necessarily all referring to the same embodiment. Furthermore, the particular features, structures, or characteristics may be combined in any suitable manner in one or more embodiments by those skilled in the art. While the foregoing has been given by way of illustrative example, many variations and modifications will be apparent to those skilled in the art without departing from the scope and spirit of the invention as herein set forth in the following claims.

What is claimed is:

1. A solar-concentrating frustum, comprising:
a.) a first material layer shaped as a conical frustum, the first layer having a solar reflecting surface;
b.) a second material layer shaped as a conical frustum, the second material layer disposed concentric to and outside the first layer, wherein the second layer is patterned with a dense array of cone-shaped indentations; and,
c.) an array of resin deposits, wherein each resin deposit is formed at the center of the cone-shaped indentation and contacting the first layer.

2. The solar-concentrating frustum of claim 2, wherein a material layer is a multilayered material.

3. A dual-axis solar-tracker, comprising:
a.) a base structure;
b.) a rotating assembly, the rotating assembly rotating within a surface formed by the base structure; the rotating assembly providing pivot rotation to an optic mounting surface, and,
c.) a linear bearing assembly at least partly within surfaces of the rotating assembly, the linear bearing providing a tilt motion to the optic mounting surface.

4. A solar receiver tube providing heated fluid and electrical power, comprising:
a.) a base structure;
b.) a receiver tube structure having photovoltaic devices, and,
c.) means for introducing an absorbing solution having fluidic properties into an annular space external to the devices, whereby solar energy passes through the absorbing fluid prior to absorption by the devices.
